(19) United States
(12) Patent Application Publication
(10) Pub. No.: US 2024/0097643 A1
(43) Pub. Date: Mar. 21, 2024

(54) PIEZOELECTRIC BULK WAVE DEVICE AND METHOD FOR MANUFACTURING THE SAME

(71) Applicant: Murata Manufacturing Co., Ltd., Nagaokakyo-shi (JP)

(72) Inventor: Kazunori INOUE, Nagaokakyo-shi (JP)

(21) Appl. No.: 18/523,989

(22) Filed: Nov. 30, 2023

Related U.S. Application Data
(63) Continuation of application No. PCT/JP2022/021940, filed on May 30, 2022.
(60) Provisional application No. 63/195,312, filed on Jun. 1, 2021.

(51) Int. Cl. H03H 9/02; H03H 3/02; H10N 30/853; H10N 30/88

(52) U.S. Cl. CPC H03H 9/02133; H03H 3/02; H03H 9/02015; H03H 9/02157; H10N 30/8536; H10N 30/883

(57) ABSTRACT

A piezoelectric bulk wave device includes a support including a support substrate, a piezoelectric layer including a first main surface on the support side and a second main surface opposite from the first main surface, and at least one functional electrode including at least a portion on at least one of the first and second main surfaces. The at least one functional electrode is supported by the support and includes a functional electrode including a portion on the first main surface of the piezoelectric layer. A cavity portion is provided in the support and superposed on a portion of the functional electrode and an entirety or substantially an entirety of the piezoelectric layer in plan view. The piezoelectric layer is supported by the functional electrode supported by the support.

### CROSS REFERENCE TO RELATED APPLICATIONS

This application claims the benefit of priority to Provisional Application No. 63/195,312 filed on Jun. 1, 2021 and is a Continuation Application of PCT Application No. PCT/JP2022/021940 filed on May 30, 2022. The entire contents of each application are hereby incorporated herein by reference.

### BACKGROUND OF THE INVENTION

### 1. Field of the Invention

The present invention relates to a piezoelectric bulk wave device and a method for manufacturing the same.

### 2. Description of the Related Art

Acoustic wave devices of the related art such as piezoelectric bulk wave devices have been widely used for, for example, filters of cellular phones. In recent years, a piezoelectric bulk wave device in which a bulk wave in the thickness slip mode is used as described in U.S. Pat. No. 10,491,192 has been proposed. In this piezoelectric bulk wave device, a piezoelectric layer is provided on a support body. A pair of electrodes are provided on the piezoelectric layer. The pair of electrodes face each other on the piezoelectric layer and are connected to different potentials. When an alternating-current voltage is applied across the electrodes, the bulk wave in the thickness slip mode is excited.

In the piezoelectric bulk wave device described in U.S. Pat. No. 10,491,192, a through hole is provided in the support body. The piezoelectric layer is provided on the support body so as to cover the through hole. Accordingly, the piezoelectric layer includes a portion supported by the support body and a portion not supported by the support body. Stress is likely to concentrate on a boundary between the portion supported by the support body and the portion not supported by the support body in the piezoelectric layer. Thus, cracks may be produced in the piezoelectric layer with the boundary as the starting point.

### SUMMARY OF THE INVENTION

Preferred embodiments of the present invention provide piezoelectric bulk wave devices in each of which cracks are unlikely to be produced in a piezoelectric layer and also provide methods for manufacturing piezoelectric bulk wave devices.

A piezoelectric bulk wave device according to a preferred embodiment of the present invention includes a support including a support substrate, a piezoelectric layer including a first main surface on a support side and a second main surface opposite from the first main surface, and at least one functional electrode at least a portion of which being provided on at least one of the first main surface and the second main surface of the piezoelectric layer. The at least one functional electrode is supported by the support and includes a functional electrode a portion of which being provided on the first main surface of the piezoelectric layer. A cavity portion is provided in the support, the cavity portion is superposed on a portion of the functional electrode and an entirety or substantially an entirety of the piezoelectric layer in plan view, and the piezoelectric layer is supported by the functional electrode supported by the support.

A method for manufacturing a piezoelectric bulk wave device according to a preferred embodiment of the present invention includes providing an interdigital transducer electrode including a pair of busbars and a plurality of electrode fingers on a third main surface of a piezoelectric substrate including the third main surface and a fourth main surface opposite from each other, forming a multilayer body including the piezoelectric substrate and a support including a support substrate, forming a piezoelectric layer including a first main surface corresponding to the third main surface and a second main surface opposite from the first main surface by grinding a fourth main surface side of the piezoelectric substrate so as to reduce a thickness of the piezoelectric substrate, and forming a cavity portion in the support. In plan view, the piezoelectric substrate includes a first portion superposed on a portion of the support in which the cavity portion is provided and a second portion not superposed on the portion of the support in which the cavity portion is provided. In the forming of the piezoelectric layer, at least an entirety or substantially an entirety of the second portion of the piezoelectric substrate is removed.

According to preferred embodiments of the present invention, piezoelectric bulk wave devices in each of which cracks are unlikely to be produced in the piezoelectric layer and methods for manufacturing such piezoelectric bulk wave devices are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a piezoelectric bulk wave device according to a first preferred embodiment of the present invention.

FIG. 2 is a schematic sectional view taken along line I-I of FIG. 1.

FIG. 3 is a schematic sectional view taken along line II-II of FIG. 1.

FIGS. 4A and 4B are schematic sectional views along an electrode finger extending direction for illustrating an interdigital transducer (IDT) electrode forming step and a connection electrode forming step in a non-limiting example of a method for manufacturing the piezoelectric bulk wave device according to the first preferred embodiment of the present invention.

FIGS. 5A to 5D are schematic sectional views along the electrode finger extending direction for illustrating a sacrificial layer forming step, a first insulating layer forming step, a first insulating layer planarizing step, and a second insulating layer forming step in the non-limiting example of the method for manufacturing the piezoelectric bulk wave device according to the first preferred embodiment of the present invention.

FIGS. 6A to 6C are schematic sectional views along the electrode finger extending direction for illustrating a piezoelectric substrate joining step, a piezoelectric layer grinding step, and a piezoelectric layer patterning step in the non-limiting example of the method for manufacturing the piezoelectric bulk wave device according to the first preferred embodiment of the present invention.

FIG. 7A is a schematic sectional view along the electrode finger extending direction for illustrating a wiring electrode forming step and a terminal electrode forming step in the non-limiting example of the method for manufacturing the piezoelectric bulk wave device according to the first preferred embodiment of the present invention, and FIGS. 7B and 7C are schematic sectional views along an electrode finger facing direction for illustrating a frequency adjustment film forming step and a sacrificial layer removing step in the non-limiting example of the method for manufacturing the piezoelectric bulk wave device according to the first preferred embodiment of the present invention.

FIGS. 8A and 8B are schematic sectional views illustrating a section not including the electrode fingers along the electrode finger extending direction for illustrating a through hole forming step and a sacrificial layer removing step in the non-limiting example of the method for manufacturing the piezoelectric bulk wave device according to the first preferred embodiment of the present invention.

FIG. 9 is a schematic plan view of a piezoelectric bulk wave device according to a second preferred embodiment of the present invention.

FIG. 10 is a schematic plan view of a piezoelectric bulk wave device according to a variant of the second preferred embodiment of the present invention.

FIG. 11 is a schematic plan view of a piezoelectric bulk wave device according to a third preferred embodiment of the present invention.

FIG. 12 is a schematic sectional view of the piezoelectric bulk wave device according to the third preferred embodiment of the present invention illustrating a section not including the electrode fingers along the electrode finger extending direction.

FIG. 13 is a schematic sectional view of the piezoelectric bulk wave device according to the third preferred embodiment of the present invention along the electrode finger facing direction.

FIGS. 14A and 14B are schematic sectional views illustrating a section not including the electrode fingers along the electrode finger extending direction for illustrating a sacrificial layer forming step, a support body forming portion forming step, and a first insulating layer forming step in an non-limiting example of a method for manufacturing the piezoelectric bulk wave device according to the third preferred embodiment of the present invention. FIG. 14C is a schematic sectional view illustrating a section not including the electrode fingers along the electrode finger extending direction for illustrating a sacrificial layer removing step in the non-limiting example of the method for manufacturing the piezoelectric bulk wave device according to the third preferred embodiment of the present invention.

FIG. 15 is a schematic plan view of a piezoelectric bulk wave device according to a fourth preferred embodiment of the present invention.

FIG. 16 is a schematic sectional view of the piezoelectric bulk wave device according to the fourth preferred embodiment of the present invention illustrating a section not including the electrode fingers along the electrode finger extending direction.

FIG. 17 is a schematic plan view of a piezoelectric bulk wave device according to a fifth preferred embodiment of the present invention.

FIG. 18 is a schematic sectional view of the piezoelectric bulk wave device according to the fifth preferred embodiment of the present invention along the electrode finger extending direction.

FIG. 19 is a schematic sectional view of the piezoelectric bulk wave device according to the fifth preferred embodiment of the present invention along the electrode finger facing direction.

FIG. 20 is a schematic sectional view of the piezoelectric bulk wave device according to a sixth preferred embodiment of the present invention along the electrode finger extending direction.

FIG. 21 is a schematic sectional view of the piezoelectric bulk wave device according to the sixth preferred embodiment of the present invention along the electrode finger facing direction.

FIG. 22 is a schematic plan view of a piezoelectric bulk wave device according to a seventh preferred embodiment of the present invention.

FIG. 23 is a schematic sectional view of the piezoelectric bulk wave device according to the seventh preferred embodiment of the present invention illustrating a section not including the electrode fingers along the electrode finger extending direction.

FIG. 24 is a schematic sectional view of the piezoelectric bulk wave device according to the seventh preferred embodiment of the present invention along the electrode finger facing direction.

FIG. 25 is a schematic sectional view illustrating portion of a piezoelectric bulk wave device according to an eighth preferred embodiment of the present invention corresponding to a section taken along line I-I of FIG. 1.

FIG. 26 is a schematic sectional view illustrating portion of the piezoelectric bulk wave device according to the eighth preferred embodiment of the present invention corresponding to a section taken along line II-II of FIG. 1.

FIG. 27 is a schematic sectional view of the piezoelectric bulk wave device according to the eighth preferred embodiment of the present invention illustrating a section which is parallel or substantially parallel to the section illustrated in FIG. 26 and which includes a second lower electrode.

FIG. 28 is a schematic sectional view illustrating a portion of a piezoelectric bulk wave device according to a variant of the eighth preferred embodiment of the present invention corresponding to the section taken along line I-I of FIG. 1.

FIG. 29A is a simplified perspective view illustrating a piezoelectric bulk wave device in which a bulk wave in the thickness slip mode is utilized. FIG. 29B is a plan view illustrating an electrode structure on a piezoelectric layer.

FIG. 30 is a sectional view taken along line A-A of FIG. 29A.

FIG. 31A is a schematic elevational sectional view for illustrating a Lamb wave propagating in a piezoelectric film of a piezoelectric bulk wave device. FIG. 31B is a schematic elevational sectional view for illustrating the bulk wave in the thickness slip mode propagating in a piezoelectric film of a piezoelectric bulk wave device.

FIG. 32 is a diagram illustrating an amplitude direction of the bulk wave in the thickness slip mode.

FIG. 33 is a diagram illustrating a resonance characteristic of the piezoelectric bulk wave device in which the bulk wave in the thickness slip mode is utilized.

FIG. 34 is a diagram illustrating the relationship between d/p and a fractional bandwidth as a resonator when a center-to-center distance between adjacent electrodes is p and the thickness of the piezoelectric layer is d.

FIG. 35 is a plan view of a piezoelectric bulk wave device in which the bulk wave in the thickness slip mode is utilized.

FIG. 36 is a diagram illustrating a resonance characteristic of the piezoelectric bulk wave device of a reference example in which a spurious emission appears.

FIG. 37 is a diagram illustrating the relationship between the fractional bandwidth and a phase rotation amount of the impedance of a spurious emission normalized with about 180 degrees as the size of the spurious emission.

FIG. 38 is a diagram illustrating the relationship between d/2p and a metallization ratio MR.

FIG. 39 is a diagram illustrating a map of the fractional bandwidth with respect to Euler angles (0°, θ, ψ) of LiNbO₃ when d/p is caused to limitlessly approach 0.

### DETAILED DESCRIPTION OF THE PREFERRED EMBODIMENTS

Hereinafter, preferred embodiments of the present invention will be described with reference to the drawings so as to clarify the present invention.

Each preferred embodiment described herein is merely exemplary, and configurations can be partially replaced or combined between different preferred embodiments.

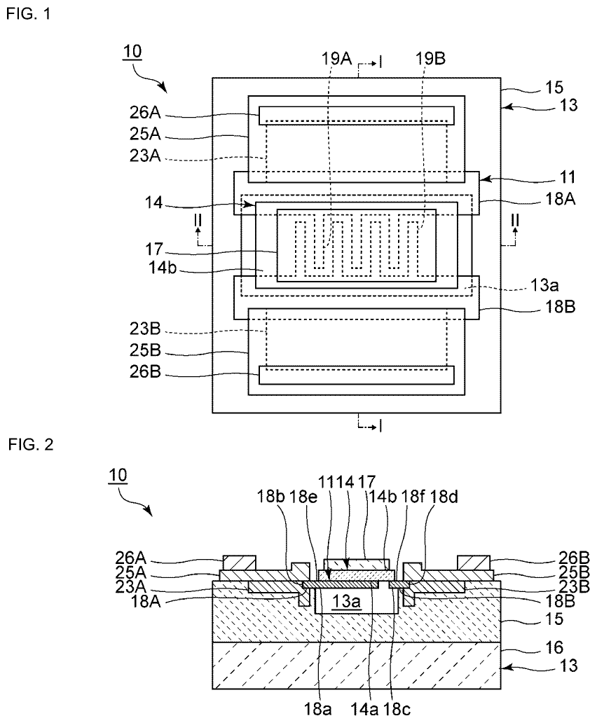

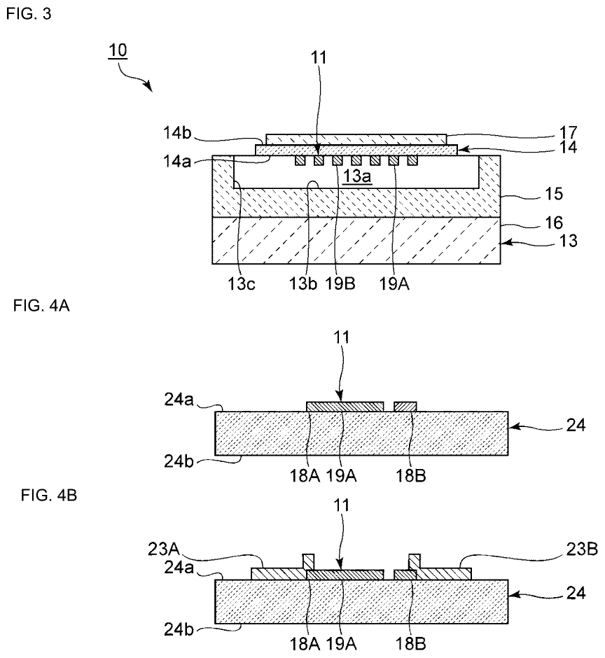

FIG. 1 is a schematic plan view of a piezoelectric bulk wave device according to a first preferred embodiment of the present invention. FIG. 2 is a schematic sectional view taken along line I-I of FIG. 1. FIG. 3 is a schematic sectional view taken along line II-II of FIG. 1.

As illustrated in FIG. 1, a piezoelectric bulk wave device 10 includes a support 13, a piezoelectric layer 14, and a functional electrode. According to the present preferred embodiment, the functional electrode is, for example, an interdigital transducer (IDT) electrode 11. Herein, the functional electrode broadly includes an electrode that functions so that an acoustic wave propagates. Thus, the functional electrode is not limited to the IDT electrode 11.

The IDT electrode 11 includes a first busbar 18A, a second busbar 18B, a plurality of first electrode fingers 19A, and a plurality of second electrode fingers 19B. The first busbar 18A and the second busbar 18B face each other. One of the ends of each of the plurality of first electrode fingers 19A is connected to the first busbar 18A. One of the ends of each of the plurality of second electrode fingers 19B is connected to the second busbar 18B. The plurality of first electrode fingers 19A and the plurality of second electrode fingers 19B are interdigitated with each other. The IDT electrode 11 may include a multilayer metal film or a single layer metal film. Hereinafter, the first electrode fingers 19A and the second electrode fingers 19B are simply referred to as electrode fingers.

As illustrated in FIG. 2, according to the present preferred embodiment, the support 13 includes a support substrate 16 and an insulating layer 15. The insulating layer 15 is provided on the support substrate 16. However, the support 13 may include only the support substrate 16. As the material of the support substrate 16, for example, a semiconductor such as silicon, ceramic such as aluminum oxide, or the like can be used. As the material of the insulating layer 15, for example, an appropriate dielectric such as silicon oxide or tantalum pentoxide can be used.

As illustrated in FIG. 3, the support 13 includes a cavity portion 13a. The support 13 includes a cavity portion bottom surface 13b and a cavity portion side wall surface 13c. More specifically, a recessed portion is provided in the insulating layer 15. This recessed portion is the cavity portion 13a according to the present preferred embodiment. A bottom surface of the recessed portion is the cavity portion bottom surface 13b. A side wall surface of the recessed portion is the cavity portion side wall surface 13c. The cavity portion side wall surface 13c is connected to the cavity portion bottom surface 13b. The cavity portion bottom surface 13b and the cavity portion side wall surface 13c of the piezoelectric bulk wave device 10 are portions of the insulating layer 15. The cavity portion 13a may extend in a region in the insulating layer 15 and the support substrate 16. Alternatively, the cavity portion 13a may be a through hole provided in the support 13. In this case, the support 13 does not include the cavity portion bottom surface 13b.

The piezoelectric layer 14 includes a first main surface 14a and a second main surface 14b. The first main surface 14a and the second main surface 14b are opposite from each other. Of the first main surface 14a and the second main surface 14b, the first main surface 14a is positioned on the support 13 side. As the material of the piezoelectric layer 14, for example, lithium niobate, lithium tantalate, zinc oxide, aluminum nitride, crystal, or lead zirconate titanate (PZT) or the like can be used.

The piezoelectric layer 14 is preferably, for example, a lithium tantalate layer such as an LiTaO₃ layer or a lithium niobate layer such as an LiNbO₃ layer.

A portion of the IDT electrode 11 is provided on the first main surface 14a of the piezoelectric layer 14. More specifically, as illustrated in FIG. 2, a portion of the first busbar 18A and a portion of the second busbar 18B are provided on the first main surface 14a of the piezoelectric layer 14. Another portion of the first busbar 18A and another portion of the second busbar 18B are provided on the insulating layer 15 of the support 13. In contrast, a plurality of electrode fingers are entirely or substantially entirely provided on the first main surface 14a of the piezoelectric layer 14. According to the present preferred embodiment, the piezoelectric layer 14 is supported by the first busbar 18A and the second busbar 18B of the IDT electrode 11.

The first busbar 18A includes a support portion 18a and a supported portion 18b. Similarly, the second busbar 18B includes a support portion 18c and a supported portion 18d. The support portion 18a of the first busbar 18A and the support portion 18c of the second busbar 18B are provided on the first main surface 14a of the piezoelectric layer 14. The supported portion 18b of the first busbar 18A and the supported portion 18d of the second busbar 18B are provided on the support 13. The IDT electrode 11 supports the piezoelectric layer 14 at each support portion. The IDT electrode 11 is supported by the support 13 at each supported portion.

A feature of the present preferred embodiment is that the cavity portion 13a of the support 13 is superposed on a portion of the IDT electrode 11 and the entirety or substantially the entirety of the piezoelectric layer 14 in plan view, and the piezoelectric layer 14 is supported by the IDT electrode 11. In the piezoelectric bulk wave device 10, the piezoelectric layer 14 and the support 13 are not in direct contact with each other. Accordingly, stress from the support 13 is not directly applied to the piezoelectric layer 14. Thus, cracks are unlikely to be produced in the piezoelectric layer 14.

Herein, the term “in plan view” means looking from a direction corresponding to an upper side in FIG. 2 or 3. In FIG. 2 or 3, for example, of the support substrate 16 side and the piezoelectric layer 14 side, the piezoelectric layer 14 side is the upper side. Hereinafter, further details of the configuration according to the present preferred embodiment are described.

The IDT electrode 11 includes portions provided on neither the piezoelectric layer 14 nor the support 13.

Specifically, these portions are a connection portion 18e and a connection portion 18f. The connection portion 18e is included in the first busbar 18A. More specifically, the connection portion 18e is positioned between the support portion 18a and the supported portion 18b in the first busbar 18A. The connection portion 18f is included in the second busbar 18B. More specifically, the connection portion 18f is positioned between the support portion 18c and the supported portion 18d in the second busbar 18B. Neither the connection portion 18e nor the connection portion 18f of the IDT electrode 11 includes irregularities in the thickness direction. Furthermore, neither the connection portion 18e nor the connection portion 18f includes irregularities in a direction perpendicular or substantially perpendicular to the thickness direction. Thus, signal losses are unlikely to be generated when the piezoelectric bulk wave device 10 is used for a radio frequency filter or the like.

As illustrated in FIG. 2, a first connection electrode 23A and a second connection electrode 23B are provided in the insulating layer 15 of the support 13. The first connection electrode 23A is connected to the first busbar 18A. The second connection electrode 23B is connected to the second busbar 18B. A portion of the first connection electrode 23A and a portion of the second connection electrode 23B are exposed from the support 13.

A first wiring electrode 25A extends in a region on the first connection electrode 23A and the insulating layer 15 of the support 13. The first wiring electrode 25A is connected to the first connection electrode 23A. A second wiring electrode 25B extends in a region on the second connection electrode 23B and the insulating layer 15. The second wiring electrode 25B is connected to the second connection electrode 23B.

A first terminal electrode 26A is provided on the first wiring electrode 25A. The first terminal electrode 26A is connected to the first wiring electrode 25A. A second terminal electrode 26B is provided on the second wiring electrode 25B. The second terminal electrode 26B is connected to the second wiring electrode 25B. The piezoelectric bulk wave device 10 is electrically connected to another element or the like through the first terminal electrode 26A and the second terminal electrode 26B.

A frequency adjustment film 17 is provided on the second main surface 14b of the piezoelectric layer 14. More specifically, the frequency adjustment film 17 is provided so as to be superposed on a portion of the IDT electrode 11 in plan view. The frequency can be adjusted by adjusting the thickness of the frequency adjustment film 17. As the material of the frequency adjustment film 17, for example, silicon oxide, silicon nitride, or the like can be used.

The piezoelectric bulk wave device 10 is configured so that a bulk wave of a thickness slip mode such as, for example, a thickness slip primary mode can be utilized. However, the piezoelectric bulk wave device 10 may be configured so that a thickness resonant mode other than the thickness slip mode can be utilized.

Hereinafter, a preferable configuration according to the present preferred embodiment is described.

The IDT electrode 11 preferably supports the piezoelectric layer 14 by using the first busbar 18A and the second busbar 18B. In this way, the IDT electrode 11 is unlikely to be damaged and can more reliably support the piezoelectric layer 14.

The thickness of the first busbar 18A and the second busbar 18B is preferably, for example, greater than or equal to about 0.5 μm, more preferably greater than or equal to about 1 μm, and even more preferably greater than or equal to about 2 μm. In this way, the piezoelectric layer 14 can be even more reliably supported.

Each of the first busbar 18A and the second busbar 18B preferably supports, for example, greater than or equal to about 80% of a side of the piezoelectric layer 14 in plan view. In this way, the piezoelectric layer 14 can be more reliably supported. According to the present preferred embodiment, the shape of the piezoelectric layer 14 is rectangular or substantially rectangular in plan view. The first busbar 18A and the second busbar 18B support two sides of four sides of the piezoelectric layer 14 in plan view. These two sides are opposite from each other.

The support 13 may include only the support substrate 16. In this case, the support 13 is preferably made of, for example, a high-resistance material.

Hereinafter, a non-limiting example of a method for manufacturing the piezoelectric bulk wave device 10 according to the present preferred embodiment is described. In the following description, a direction in which adjacent electrode fingers face each other is defined as an electrode finger facing direction, and a direction in which the plurality of electrode fingers extend is defined as an electrode finger extending direction. According to the present preferred embodiment, the electrode finger facing direction and the electrode finger extending direction are perpendicular or substantially perpendicular to each other.

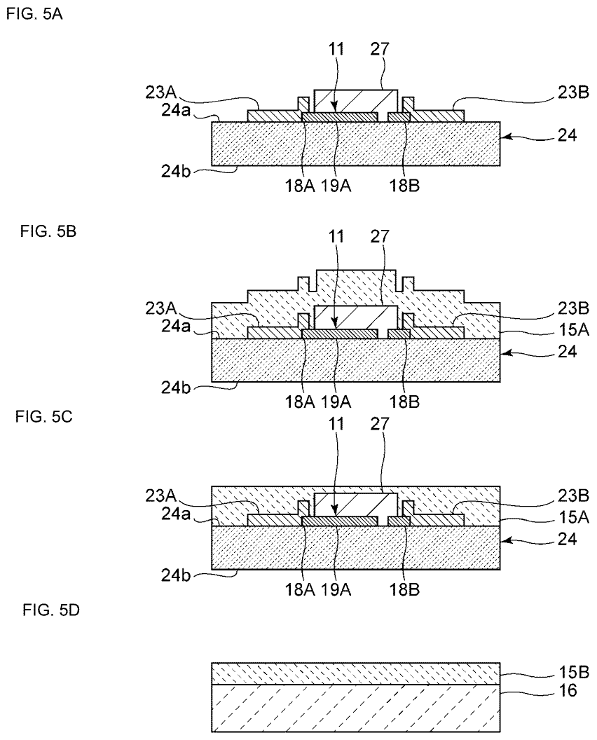

FIGS. 4A and 4B are schematic sectional views along the electrode finger extending direction for illustrating an IDT electrode forming step and a connection electrode forming step in a non-limiting example of the method for manufacturing the piezoelectric bulk wave device according to the first preferred embodiment. FIGS. 5A to 5D are schematic sectional views along the electrode finger extending direction for illustrating a sacrificial layer forming step, a first insulating layer forming step, a first insulating layer planarizing step, and a second insulating layer forming step in the non-limiting example of the method for manufacturing the piezoelectric bulk wave device according to the first preferred embodiment.

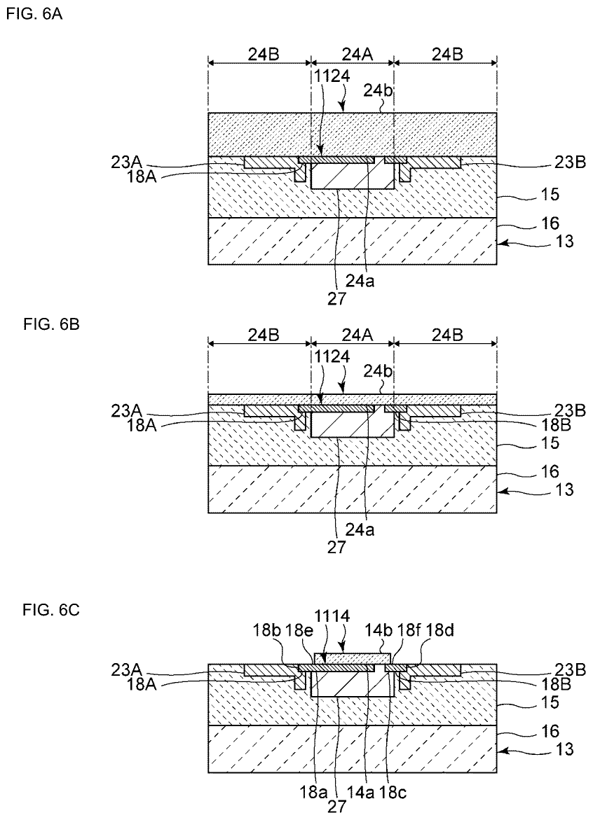

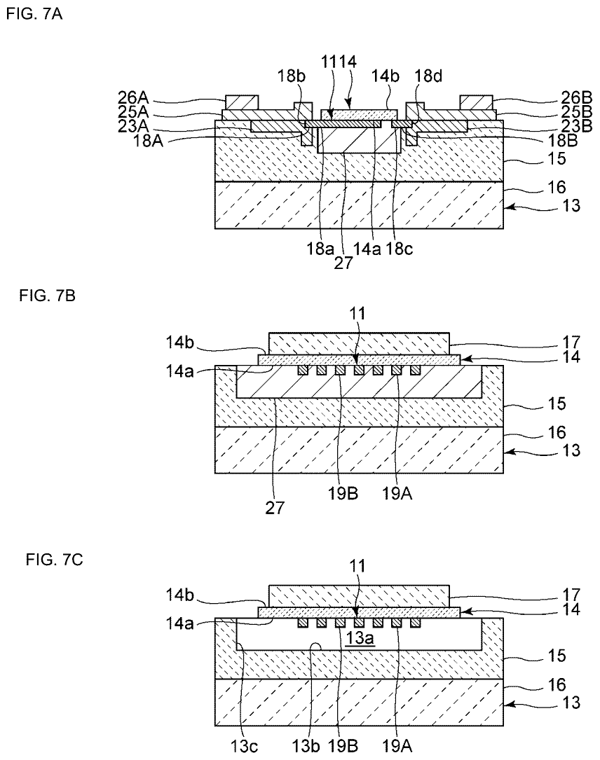

FIGS. 6A to 6C are schematic sectional views along the electrode finger extending direction for illustrating a piezoelectric substrate joining step, a piezoelectric layer grinding step, and a piezoelectric layer patterning step in the non-limiting example of the method for manufacturing the piezoelectric bulk wave device according to the first preferred embodiment. FIG. 7A is a schematic sectional view along the electrode finger extending direction for illustrating a wiring electrode forming step and a terminal electrode forming step in the non-limiting example of the method for manufacturing the piezoelectric bulk wave device according to the first preferred embodiment. FIGS. 7B and 7C are schematic sectional views along the electrode finger facing direction for illustrating a frequency adjustment film forming step and a sacrificial layer removing step in the non-limiting example of the method for manufacturing the piezoelectric bulk wave device according to the first preferred embodiment.

As illustrated in FIG. 4A, a piezoelectric substrate 24 is prepared. The piezoelectric substrate 24 is included in a piezoelectric layer according to a preferred embodiment of the present invention. The piezoelectric substrate 24 includes a third main surface 24a and a fourth main surface 24b. The third main surface 24a and the fourth main surface 24b are opposite from each other. The IDT electrode 11 is provided on the third main surface 24a of the piezoelectric substrate 24. The IDT electrode 11 can be formed with, for example, a lift-off method or the like for which a sputtering method, a vacuum deposition method, or the like is used.

Next, as illustrated in FIG. 4B, the first connection electrode 23A and the second connection electrode 23B are provided on the third main surface 24a of the piezoelectric substrate 24. More specifically, the first connection electrode 23A is provided so as to cover a portion of the first busbar 18A. In this way, the first connection electrode 23A is connected to the first busbar 18A. Similarly, the second connection electrode 23B is provided so as to cover a portion of the second busbar 18B. In this way, the second connection electrode 23B is connected to the second busbar 18B. The first connection electrode 23A and the second connection electrode 23B can be formed with, for example, the lift-off method or the like for which the sputtering method, the vacuum deposition method, or the like is used.

Next, as illustrated in FIG. 5A, a sacrificial layer 27 is provided on the third main surface 24a of the piezoelectric substrate 24. The sacrificial layer 27 is provided so as to cover a portion of the first busbar 18A, a portion of the second busbar 18B, and the plurality of electrode fingers of the IDT electrode 11. In contrast, neither the first connection electrode 23A nor the second connection electrode 23B is covered with the sacrificial layer 27. As the material of the sacrificial layer 27, for example, ZnO, SiO₂, Cu, resin, or the like can be used.

Next, as illustrated in FIG. 5B, a first insulating layer 15A is provided on the third main surface 24a of the piezoelectric substrate 24. More specifically, the first insulating layer 15A is provided so as to cover the IDT electrode 11 and the sacrificial layer 27. The first insulating layer 15A can be formed with, for example, the sputtering method, the vacuum deposition method, or the like. Next, as illustrated in FIG. 5C, the first insulating layer 15A is planarized. In planarizing the first insulating layer 15A, for example, grinding, a chemical mechanical polishing (CMP) method, or the like can be used.

Meanwhile, as illustrated in FIG. 5D, a second insulating layer 15B is provided on one main surface of the support substrate 16. Next, the first insulating layer 15A illustrated in FIG. 5C and the second insulating layer 15B illustrated in FIG. 5D are joined to each other. In this way, as illustrated in FIG. 6A, the insulating layer 15 is formed, and the support substrate 16 and the piezoelectric substrate 24 are joined to form a multilayer body. The multilayer body includes the support 13 and the piezoelectric substrate 24.

Next, as illustrated in FIG. 6B, the thickness of the piezoelectric substrate 24 is adjusted. More specifically, the thickness of the piezoelectric substrate 24 is reduced by grinding or polishing the fourth main surface 24b side in the piezoelectric substrate 24. In adjusting the thickness of the piezoelectric substrate 24, for example, grinding, the CMP method, an ion slice method, etching, or the like can be used.

Meanwhile, the piezoelectric substrate 24 includes a first portion 24A and a second portion 24B. More specifically, the first portion 24A is superposed on the sacrificial layer 27 in plan view. The second portion 24B is not superposed on the sacrificial layer 27 in plan view. That is, the first portion 24A is, in plan view, a portion superposed on a portion of the support 13 where the cavity portion is provided. The second portion 24B is, in plan view, a second portion not superposed on the portion of the support 13 where the cavity portion is provided.

Next, at least the entirety or substantially the entirety of the second portion 24B of the piezoelectric substrate 24 is removed. In this way, as illustrated in FIG. 6C, the piezoelectric layer 14 is obtained. The first main surface 14a of the piezoelectric layer 14 corresponds to the third main surface 24a of the piezoelectric substrate 24. The second main surface 14b of the piezoelectric layer 14 corresponds to the fourth main surface 24b of the piezoelectric substrate 24. With the step of forming the piezoelectric layer 14, the first busbar 18A, the second busbar 18B, the first connection electrode 23A, and the second connection electrode 23B are brought into an exposed state.

In the manufacture of the piezoelectric bulk wave device 10 according to the present preferred embodiment, a portion of the first portion 24A illustrated in FIG. 6B is also removed in the step of forming the piezoelectric layer 14. Thus, a portion of the sacrificial layer 27 is brought into an exposed state.

Next, as illustrated in FIG. 7A, the first wiring electrode 25A is provided so as to extend in a region on the first connection electrode 23A and the insulating layer 15 of the support 13. In this way, the first wiring electrode 25A is connected to the first connection electrode 23A. Furthermore, the second wiring electrode 25B is provided so as to extend in a region on the second connection electrode 23B and the insulating layer 15. In this way, the second wiring electrode 25B is connected to the second connection electrode 23B. The first wiring electrode 25A and the second wiring electrode 25B can be formed with, for example, the lift-off method or the like for which the sputtering method, the vacuum deposition method, or the like is used.

Next, the first terminal electrode 26A is provided on the first wiring electrode 25A. Furthermore, the second terminal electrode 26B is provided on the second wiring electrode 25B. The first terminal electrode 26A and the second terminal electrode 26B can be formed with, for example, the lift-off method or the like for which the sputtering method, the vacuum deposition method, or the like is used.

Next, as illustrated in FIG. 7B, the frequency adjustment film 17 is provided on the second main surface 14b of the piezoelectric layer 14. The frequency adjustment film 17 is superposed on portion of the IDT electrode 11 in plan view. The frequency adjustment film 17 can be formed with, for example, the sputtering method, the vacuum deposition method, or the like.

Next, as illustrated in FIG. 7C, the sacrificial layer 27 is removed. The sacrificial layer 27 can be removed with, for example, etching using an etchant or the like. More specifically, in the step illustrated in FIG. 6C, a portion of the sacrificial layer 27 is in the exposed state in a portion between the piezoelectric layer 14 and the insulating layer 15 in plan view. The sacrificial layer 27 in the recessed portion of the insulating layer 15 is removed from this portion.

Next, the frequency adjustment film 17 is subjected to trimming and the thickness of the frequency adjustment film 17 is adjusted so as to adjust the frequency. Thus, the piezoelectric bulk wave device 10 illustrated in FIGS. 1 to 3 is obtained.

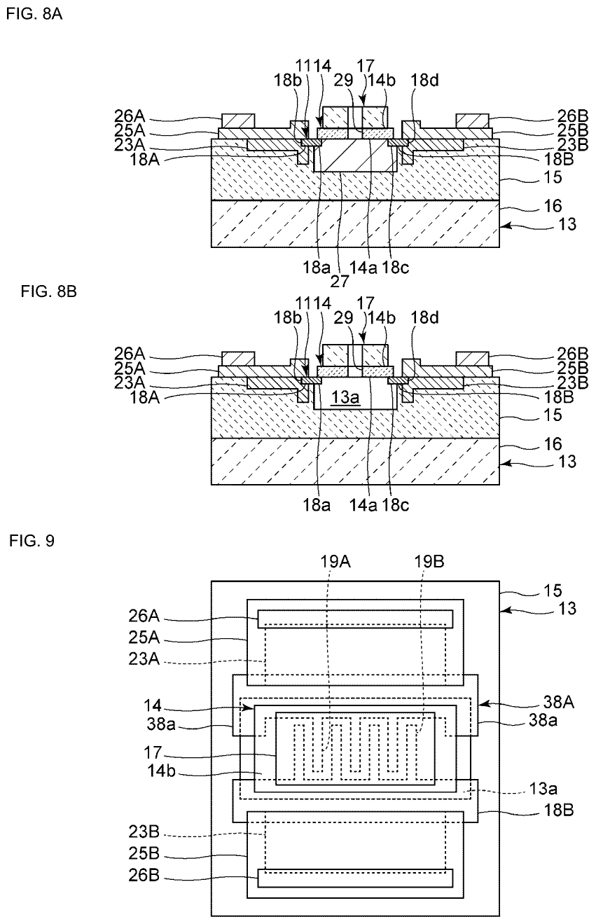

The removal of the sacrificial layer 27 may be performed by using through holes. More specifically, for example, as illustrated in FIG. 8A, a plurality of through holes 29 are provided, after the step illustrated in FIG. 7B, in the piezoelectric layer 14 and the frequency adjustment film 17 to extend to the sacrificial layer 27. The through holes 29 are continuously provided in the piezoelectric layer 14 and the frequency adjustment film 17. The through holes 29 can be formed with, for example, a reactive ion etching (RIE) method or the like. It is noted that FIG. 8A illustrates a section not including the electrode fingers.

Next, the sacrificial layer 27 is removed by utilizing the through holes 29. More specifically, the etchant is caused to flow in through the through holes 29 so as to remove the sacrificial layer 27 in the recessed portion of the insulating layer 15. In this way, the cavity portion 13a is formed as illustrated in FIG. 8B. The through holes 29 may be provided in a portion of the piezoelectric layer 14 where the frequency adjustment film 17 is not provided. In this case, the through holes 29 are not necessarily provided in the frequency adjustment film 17.

In the manufacture of the piezoelectric bulk wave device 10, as illustrated in FIG. 4A, the IDT electrode 11 is provided on the piezoelectric substrate 24. As illustrated in FIGS. 6B and 6C, when the entirety or substantially the entirety of the second portion 24B and a portion of the first portion 24A of the piezoelectric substrate 24 are removed, the support portion 18a, the supported portion 18b, and the connection portion 18e of the IDT electrode 11 are formed. At the same time, the support portion 18c, the supported portion 18d, and the connection portion 18f are formed. As described above, the connection portion 18e and the connection portion 18f are formed in a state in which the IDT electrode 11 is fixed. Accordingly, neither the connection portion 18e nor the connection portion 18f includes irregularities in the thickness direction or the direction perpendicular or substantially perpendicular to the thickness direction.

Meanwhile, as illustrated in FIG. 2, the IDT electrode 11 as the functional electrode is provided only on the first main surface 14a of the piezoelectric layer 14 according to the present preferred embodiment. According to preferred embodiments of the present invention, it is sufficient that at least a portion of at least one functional electrode is provided at least one of the first main surface 14a and the second main surface 14b. It is sufficient that the at least one functional electrode include a functional electrode which is supported by the support 13 and a portion of which is provided on the first main surface 14a.

FIG. 9 is a schematic plan view of a piezoelectric bulk wave device according to a second preferred embodiment of the present invention.

The present preferred embodiment is different from the first preferred embodiment in that a first busbar 38A has a U shape in plan view according to the present preferred embodiment. Other than the above-described point, the piezoelectric bulk wave device according to the present preferred embodiment has the same or similar configuration as that of the piezoelectric bulk wave device 10 according to the first preferred embodiment. The shape of the second busbar 18B in plan view is a linear shape similarly to the first preferred embodiment.

The first busbar 38A includes two projecting portions 38a. Each of the projecting portions 38a projects from the first busbar 38A to the second busbar 18B side. The projecting portions 38a are positioned at respective end portions of the first busbar 38A in a direction parallel or substantially parallel to the electrode finger facing direction. A portion of each of the projecting portions 38a is provided on the first main surface 14a of the piezoelectric layer 14. Another portion of the projecting portion 38a is provided on the insulating layer 15 of the support 13. Accordingly, the projecting portions 38a support respective sides of the piezoelectric layer 14 in plan view.

The shape of the piezoelectric layer 14 is rectangular or substantially rectangular in plan view. The first busbar 38A supports three sides of four sides of the piezoelectric layer 14 in plan view. Furthermore, with the first busbar 38A and the second busbar 18B, all of the sides of the piezoelectric layer 14 are supported. In this way, the piezoelectric layer 14 can be more reliably supported.

The width of each of the projecting portions 38a of the first busbar 38A is preferably greater than the width of each of the electrode fingers. In this way, the piezoelectric layer 14 can be even more reliably supported. Herein, the width of the projecting portion 38a is a dimension of the projecting portion 38a in the direction parallel or substantially parallel to the electrode finger facing direction. The width of the electrode finger is a dimension of the electrode finger in the electrode finger facing direction.

According to the present preferred embodiment, the first busbar 38A has a U shape in plan view, and the second busbar 18B has a linear shape in plan view. Thus, short circuiting between the first busbar 38A and the second busbar 18B is unlikely to occur. However, the second busbar 18B may also have a U shape in plan view.

The length of the projecting portion 38a of the first busbar 38A is smaller than the length of the first electrode fingers 19A. However, the length of the projecting portion 38a of the first busbar 38A may be greater than or equal to the length of the first electrode fingers 19A. Herein, the length of the projecting portion 38a is a dimension of the projecting portion 38a in a direction parallel or substantially parallel to the electrode finger extending direction. The length of the electrode finger is a dimension of the electrode finger in the electrode finger extending direction.

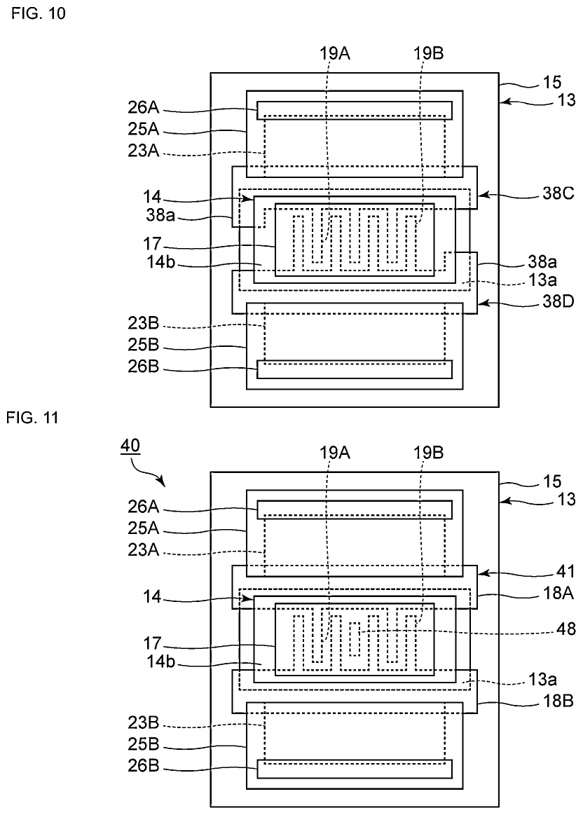

Neither the shape of the first busbar 38A nor the shape of the second busbar 18B is limited to the above description. For example, as in a variant of the second preferred embodiment illustrated in FIG. 10, a first busbar 38C and a second busbar 38D may have an L shape in plan view. More specifically, the first busbar 38C and the second busbar 38D each have a single projecting portion 38a. The projecting portion 38a of each of the first busbar 38C and the second busbar 38D is positioned at one of the end portions in the direction parallel or substantially parallel to the electrode finger facing direction. The projecting portion 38a of the second busbar 38D projects from the second busbar 38D to the first busbar 38C side.

The first busbar 38C and the second busbar 38D are point symmetrically disposed around the center of the piezoelectric layer 14 as the axis of symmetry. Accordingly, the first busbar 38C and the second busbar 38D each support two sides of the piezoelectric layer 14 in plan view. Furthermore, with the first busbar 38C and the second busbar 38D, all of the sides of the piezoelectric layer 14 are supported. In this way, the piezoelectric layer 14 can be more reliably supported. However, the dimension of the first busbar 38C and the dimension of the second busbar 38D in each direction may be different from each other. The disposition of the first busbar 38C and the second busbar 38D is not necessarily completely point symmetric, and may be substantially point symmetric.

The projecting portions 38a of the first busbar 38C and the projecting portions 38a of the second busbar 38D are disposed such that the plurality of electrode fingers are interposed therebetween. Accordingly, the projecting portion 38a of the first busbar 38C and the projecting portions 38a of the second busbar 38D do not face each other in the direction parallel or substantially parallel to the electrode finger extending direction. Thus, short circuiting between the first busbar 38C and the second busbar 38D is unlikely to occur.

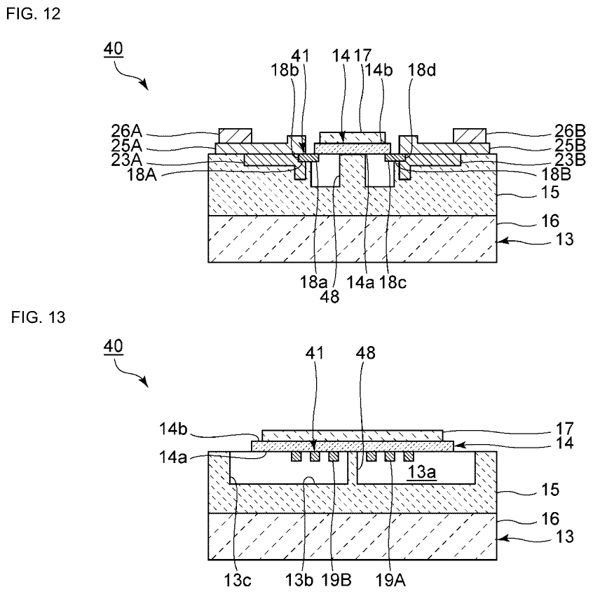

FIG. 11 is a schematic plan view of a piezoelectric bulk wave device according to a third preferred embodiment of the present invention. FIG. 12 is a schematic sectional view of the piezoelectric bulk wave device according to the third preferred embodiment illustrating a section not including the electrode fingers along the electrode finger extending direction. FIG. 13 is a schematic sectional view of the piezoelectric bulk wave device according to the third preferred embodiment along the electrode finger facing direction.

As illustrated in FIGS. 11 to 13, the present preferred embodiment is different from the first preferred embodiment in that a support body 48 is provided in the cavity portion 13a of the support 13 according to the present preferred embodiment. The support body 48 together with an IDT electrode 41 supports the piezoelectric layer 14. As illustrated in FIG. 13, the present preferred embodiment is also different from the first preferred embodiment in that two of the second electrode fingers 19B of the plurality of second electrode fingers 19B are adjacent to each other in the IDT electrode 41 according to the present preferred embodiment. In a portion of the IDT electrode 41 other than the portion where two second electrode fingers 19B are adjacent to each other, the first electrode fingers 19A and the second electrode fingers 19B are adjacent to each other. Other than the above-described points, a piezoelectric bulk wave device 40 according to the present preferred embodiment has the same or similar configuration as that of the piezoelectric bulk wave device 10 according to the first preferred embodiment.

The support body 48 is provided on the cavity portion bottom surface 13b in the support 13. The support body 48 extends from the cavity portion bottom surface 13b to the piezoelectric layer 14 side and supports the piezoelectric layer 14. More specifically, the support body 48 is provided between the second electrode fingers 19B adjacent to each other. That is, the support body 48 supports a portion of the piezoelectric layer 14 between a portion where the second electrode fingers 19B adjacent to each other are provided. According to the present preferred embodiment, the support body 48 is not in contact with the IDT electrode 41.

According to the present preferred embodiment, the support body 48 is integral with the support 13. More specifically, the support body 48 is made of the same material as that of the insulating layer 15 and is integral with the insulating layer 15. However, the support body 48 may be provided as a separate body separated from the support 13.

The piezoelectric bulk wave device 40 includes a single support body 48. However, the piezoelectric bulk wave device 40 may include a plurality of support bodies 48. The support body 48 is not in contact with the cavity portion side wall surface 13c of the cavity portion 13a. However, the support body 48 may be in contact with the cavity portion side wall surface 13c.

Also according to the present preferred embodiment, as in the first preferred embodiment, the cavity portion 13a of the support 13 is superposed on the entirety or substantially the entirety of the piezoelectric layer 14 in plan view, and the piezoelectric layer 14 is supported by the IDT electrode 41. In this way, the stress from the support 13 is not directly applied to the piezoelectric layer 14, and accordingly, cracks are unlikely to be produced in the piezoelectric layer 14. In addition, since the piezoelectric layer 14 is also supported by the support body 48, the piezoelectric layer 14 is unlikely to be brought into contact with the cavity portion bottom surface 13b. Accordingly, degradation of the electrical characteristics of the piezoelectric bulk wave device 40 can be reduced or prevented.

The piezoelectric bulk wave device 40 is configured so that the bulk wave in the thickness slip mode can be utilized. When an alternating-current voltage is applied to the IDT electrode 41, the above-described bulk wave is excited in a plurality of exciting regions. The exciting regions are regions where the first electrode fingers 19A and the second electrode fingers 19B adjacent to each other are superposed on each other when seen in the electrode finger facing direction. More specifically, each of the exciting regions is a region between a corresponding one of pairs of the first electrode fingers 19A and the second electrode fingers 19B. More specifically, the exciting region is a region from the center of the first electrode finger 19A in the electrode finger facing direction to the center of the second electrode finger 19B in the electrode finger facing direction. Accordingly, the piezoelectric bulk wave device 40 is equivalent to an element in which a plurality of resonators are connected in parallel. Thus, even when two of the second electrode fingers 19B of the plurality of second electrode fingers 19B are adjacent to each other as in the present preferred embodiment, the electrical characteristics are unlikely to degrade.

The support body 48 is preferably superposed on the center of the piezoelectric layer 14 in the direction parallel or substantially parallel to the electrode finger extending direction in plan view. Alternatively, the support body 48 is preferably superposed on the center of the piezoelectric layer 14 in the direction parallel or substantially parallel to the electrode finger facing direction in plan view. In this way, the piezoelectric layer 14 can be effectively supported by the support body 48.

Hereinafter, a non-limiting example of a method for manufacturing the piezoelectric bulk wave device 40 according to the present preferred embodiment is described.

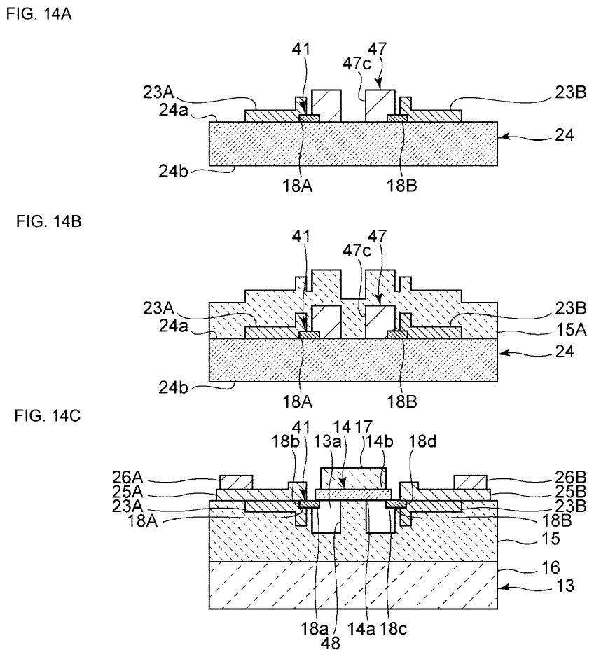

FIGS. 14A and 14B are schematic sectional views illustrating a section not including the electrode fingers along the electrode finger extending direction for illustrating a sacrificial layer forming step, a support body forming portion forming step, and a first insulating layer forming step in a non-limiting example of the method for manufacturing the piezoelectric bulk wave device according to the third preferred embodiment. FIG. 14C is a schematic sectional view illustrating a section not including the electrode fingers along the electrode finger extending direction for illustrating a sacrificial layer removing step in the non-limiting example of the method for manufacturing the piezoelectric bulk wave device according to the third preferred embodiment.

As illustrated in FIG. 14A, similarly to the non-limiting example of manufacturing the piezoelectric bulk wave device 10 according to the first preferred embodiment, the IDT electrode 41 and a sacrificial layer 47 are provided on the third main surface 24a of the piezoelectric substrate 24. Next, a support body forming portion 47c is provided in the sacrificial layer 47. Specifically, the support body forming portion 47c is a hole extending through the sacrificial layer 47. The support body forming portion 47c has a shape corresponding to the support body 48 illustrated in, for example, FIG. 12. When the plurality of support bodies 48 are formed, a plurality of support body forming portions 47c may be formed. It is sufficient that at least one support body forming portion 47c be formed in the sacrificial layer 47.

Next, as illustrated in FIG. 14B, the first insulating layer 15A is provided on the third main surface 24a of the piezoelectric substrate 24. More specifically, the first insulating layer 15A covers the IDT electrode 41 and the sacrificial layer 47. At this time, the first insulating layer 15A enables the support body forming portion 47c of the sacrificial layer 47 to be filled with the first insulating layer 15A.

Steps after that can be performed the same as or similarly to the above-described example of the method for manufacturing the piezoelectric bulk wave device 10 according to the first preferred embodiment. The cavity portion 13a and the support body 48 can be formed as illustrated in FIG. 14C by removing the sacrificial layer 47 the same as or similarly to the method illustrated in FIGS. 7B and 7C. The plurality of support bodies 48 may be formed. After that, the frequency adjustment film 17 is subjected to trimming and the thickness of the frequency adjustment film 17 is adjusted so as to adjust the frequency. Thus, the piezoelectric bulk wave device 40 according to the present preferred embodiment illustrated in FIGS. 11 to 13 is obtained.

The removal of the sacrificial layer 47 may be performed by using through holes. More specifically, for example, after the frequency adjustment film 17 has been formed similarly to the step illustrated in FIG. 7B, the plurality of through holes 29 are provided in the piezoelectric layer 14 and the frequency adjustment film 17 as illustrated in FIG. 8A. At this time, the through holes 29 are provided so as to extend to the sacrificial layer 47. Next, the sacrificial layer 47 is removed by utilizing the through holes 29. More specifically, the etchant is caused to flow in through the through holes 29 so as to remove the sacrificial layer 47 in the recessed portion of the insulating layer 15. In this way, the cavity portion 13a and at least one support body 48 are formed as illustrated in FIG. 14C.

Hereinafter, other examples of the configuration including the support body are described according to fourth to seventh preferred embodiments of the present invention. Also according to the fourth to seventh preferred embodiments, cracks are unlikely to be produced in the piezoelectric layer as in the third preferred embodiment. Furthermore, the piezoelectric layer is unlikely to be brought into contact with the cavity portion bottom surface, and accordingly, the electrical characteristics of the piezoelectric bulk wave device are unlikely to degrade.

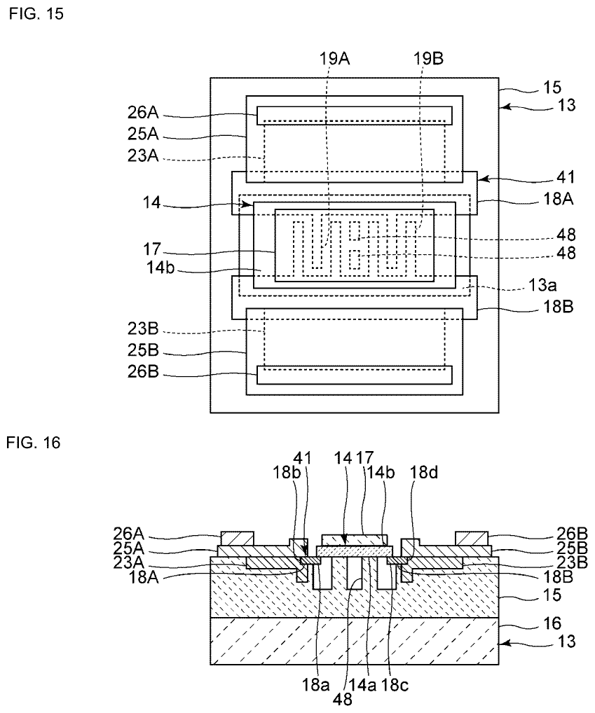

FIG. 15 is a schematic plan view of a piezoelectric bulk wave device according to the fourth preferred embodiment. FIG. 16 is a schematic sectional view of the piezoelectric bulk wave device according to the fourth preferred embodiment illustrating a section not including the electrode fingers along the electrode finger extending direction.

As illustrated in FIGS. 15 and 16, the present preferred embodiment is different from the third preferred embodiment in that the plurality of support bodies 48 are provided according to the present preferred embodiment. Specifically, two support bodies 48 are provided. Other than the above-described point, the piezoelectric bulk wave device according to the present preferred embodiment has the same or similar configuration as that of the piezoelectric bulk wave device 40 according to the third preferred embodiment.

The plurality of support bodies 48 are arranged in the direction parallel or substantially parallel to the electrode finger extending direction. The plurality of support bodies 48 are provided between the second electrode fingers 19B adjacent to each other in the IDT electrode 41. However, the position of the plurality of support bodies 48 is not limited to the above description.

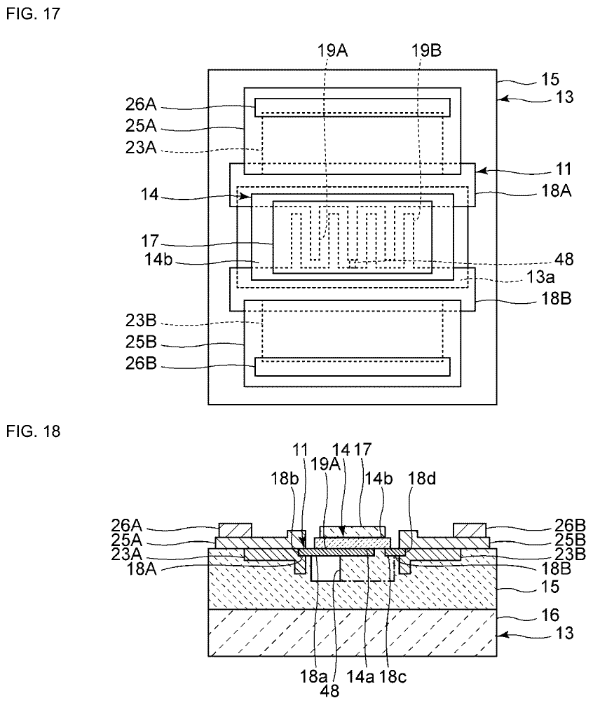

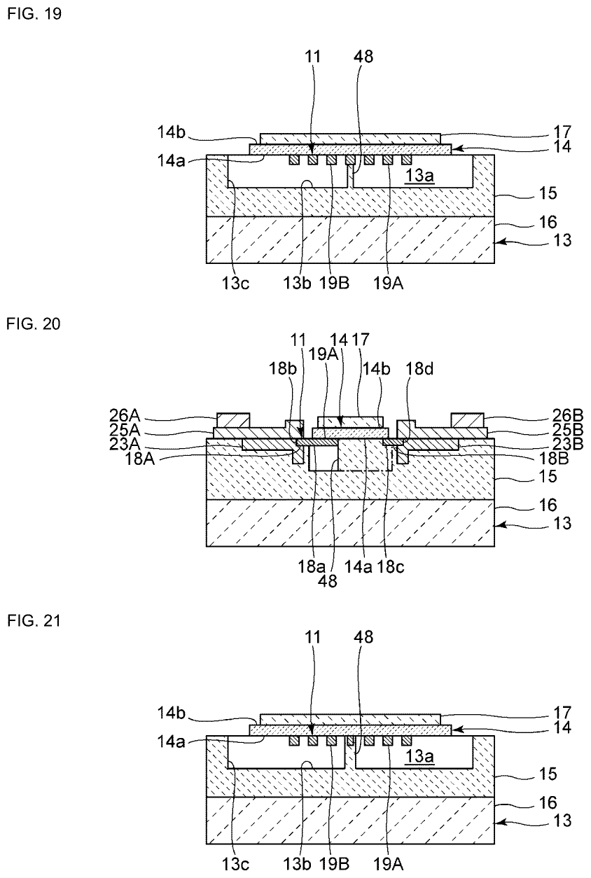

FIG. 17 is a schematic plan view of a piezoelectric bulk wave device according to the fifth preferred embodiment. FIG. 18 is a schematic sectional view of the piezoelectric bulk wave device according to the fifth preferred embodiment along the electrode finger extending direction. FIG. 19 is a schematic sectional view of the piezoelectric bulk wave device according to the fifth preferred embodiment along the electrode finger facing direction. Dotted-chain lines of FIG. 18 indicate a boundary between the support body 48 and the support 13. This is similarly applied to schematic sectional views other than FIG. 18.

As illustrated in FIG. 17, the present preferred embodiment is different from the third preferred embodiment in that all of the first electrode fingers 19A and second electrode fingers 19B are adjacent to each other in the IDT electrode 11 according to the present preferred embodiment. The IDT electrode 11 is configured the same as or similarly to that of the first preferred embodiment. The present preferred embodiment is also different from the third preferred embodiment in that, as illustrated in FIG. 18, the support body 48 is in contact with the IDT electrode 11 according to the present preferred embodiment. Furthermore, the present preferred embodiment is also different from the third preferred embodiment in that the support body 48 is in contact with the cavity portion side wall surface 13c according to the present preferred embodiment. Other than the above-described points, the piezoelectric bulk wave device according to the present preferred embodiment has the same or similar configuration as that of the piezoelectric bulk wave device 40 according to the third preferred embodiment.

The support body 48 extends from the cavity portion bottom surface 13b and the cavity portion side wall surface 13c. The support body 48 is in contact with the first electrode finger 19A, the second busbar 18B, and the piezoelectric layer 14. The support body 48 according to the present preferred embodiment is integral with the support 13 as in the third preferred embodiment. Accordingly, the support body 48 is made of a dielectric. As illustrated in FIG. 19, the width of the support body 48 is smaller than the width of each of the electrode fingers. Herein, the width of the support body 48 is a dimension of the support body 48 in the direction parallel or substantially parallel to the electrode finger facing direction.

FIG. 20 is a schematic sectional view of the piezoelectric bulk wave device according to a sixth preferred embodiment of the present invention along the electrode finger extending direction. FIG. 21 is a schematic sectional view of the piezoelectric bulk wave device according to the sixth preferred embodiment along the electrode finger facing direction.

As illustrated in FIGS. 20 and 21, the present preferred embodiment is different from the fifth preferred embodiment in that the support body 48 covers a portion of one of the first electrode fingers 19A according to the present preferred embodiment. The present preferred embodiment is also different from the fifth preferred embodiment in that the width of the one first electrode finger 19A covered with the support body 48 is smaller than the width of the other first electrode fingers 19A according to the present preferred embodiment. Other than the above-described points, the piezoelectric bulk wave device according to the present preferred embodiment has the same or similar configuration as that of the piezoelectric bulk wave device according to the fifth preferred embodiment.

The width of the support body 48 is greater than the width of the first electrode finger 19A that the support body 48 covers. The width of the first electrode finger 19A that the support body 48 covers may be the same or substantially the same as the width of the other electrode fingers. In this case, the support body 48 may cover portion of the first electrode finger 19A.

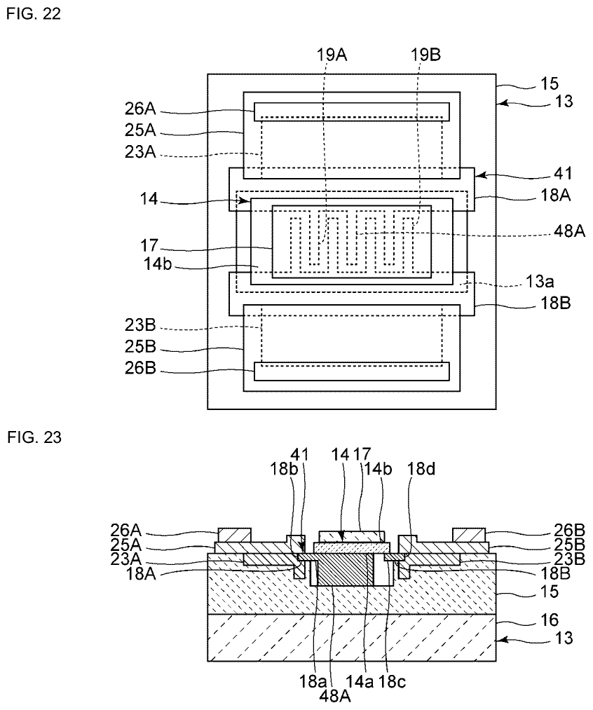

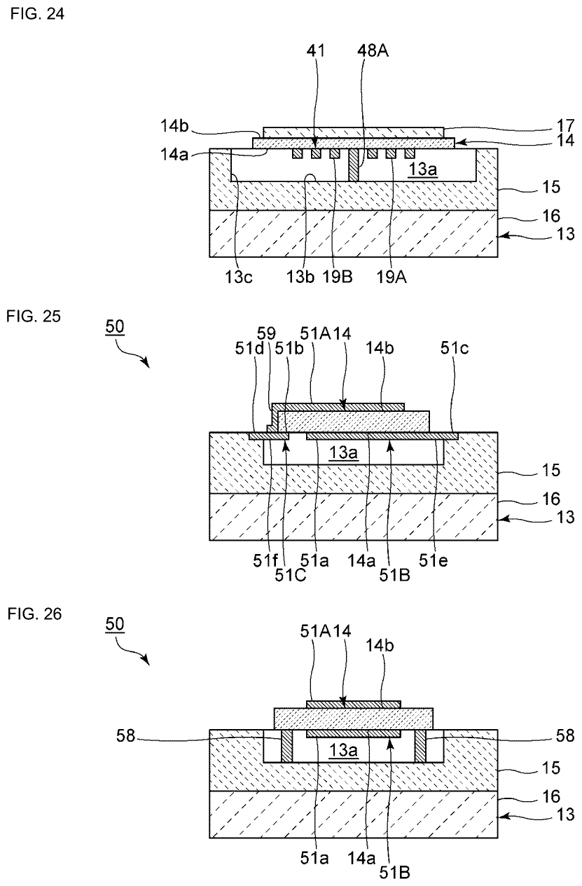

FIG. 22 is a schematic plan view of a piezoelectric bulk wave device according to a seventh preferred embodiment of the present invention. FIG. 23 is a schematic sectional view of the piezoelectric bulk wave device according to the seventh preferred embodiment illustrating a section not including the electrode fingers along the electrode finger extending direction. FIG. 24 is a schematic sectional view of the piezoelectric bulk wave device according to the seventh preferred embodiment along the electrode finger facing direction.

The present preferred embodiment is different from the third preferred embodiment in that a support body 48A is provided as a separate body spaced apart from the support 13 according to the present preferred embodiment. The present preferred embodiment is also different from the third preferred embodiment in that the support body 48A is made of metal and connected to the first busbar 18A according to the present preferred embodiment. The support body 48A is not electrically connected to the second busbar 18B or the second electrode fingers 19B. Other than the above-described points, the piezoelectric bulk wave device according to the present preferred embodiment has the same or similar configuration as that of the piezoelectric bulk wave device 40 according to the third preferred embodiment.

The piezoelectric bulk wave device according to the present preferred embodiment is configured so that the bulk wave in the thickness slip mode can be utilized. The bulk wave is excited the most in the center of the exciting region. The center of the exciting region is positioned in the middle or approximate middle between the first electrode finger 19A and the second electrode finger 19B adjacent to each other. Accordingly, even when the support body 48A is electrically connected to the first busbar 18A, the electrical characteristics of the piezoelectric bulk wave device are unlikely to degrade. The support body 48A is not necessarily electrically connected to the IDT electrode 41.

As the material of the support body 48A, the same type of metal as the material of the IDT electrode 41 is used. However, as the material of the support body 48A, a different type of metal from the material of the IDT electrode 41 may be used.

Alternatively, as the material of the support body 48A, a dielectric may be used. In this case, as the material of the support body 48A, a different type of dielectric from the material of the insulating layer 15 of the support 13 may be used.

According to the present preferred embodiment, the length of the support body 48A is the same or substantially the same as the length of the first electrode fingers 19A. However, the length of the support body 48A may be different from the length of the first electrode fingers 19A. Herein, the length of the support body 48A is a dimension of the support body 48 in the direction parallel or substantially parallel to the electrode finger extending direction.

The support body 48A is not in contact with the cavity portion side wall surface 13c. However, the support body 48A may be in contact with the cavity portion side wall surface 13c. When the support body 48A is electrically connected to the first busbar 18A, the support body 48A is preferably in contact with portion of the cavity portion side wall surface 13c positioned on the first busbar 18A side.

The piezoelectric bulk wave device according to the first to seventh preferred embodiments is configured so that the bulk wave in the thickness slip mode can be utilized. However, the piezoelectric bulk wave device according to the present invention may be, for example, a bulk acoustic wave (BAW) element. An example of this is described with an eighth preferred embodiment.

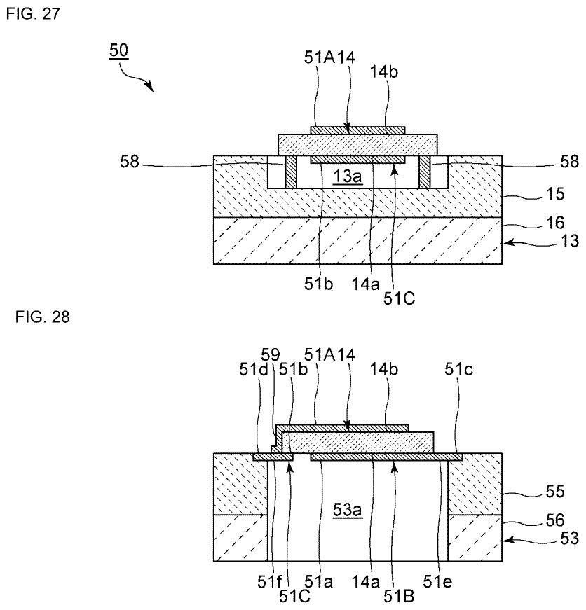

FIG. 25 is a schematic sectional view illustrating a portion of a piezoelectric bulk wave device according to the eighth preferred embodiment corresponding to a section taken along line I-I of FIG. 1. FIG. 26 is a schematic sectional view illustrating portion of the piezoelectric bulk wave device according to the eighth preferred embodiment corresponding to a section taken along line II-II of FIG. 1. FIG. 27 is a schematic sectional view of the piezoelectric bulk wave device according to the eighth preferred embodiment illustrating a section which is parallel to the section illustrated in FIG. 26 and which includes a second lower electrode.

As illustrated in FIG. 25, the present preferred embodiment is different from the first preferred embodiment in that a plurality of functional electrodes are provided according to the present preferred embodiment. Specifically, the plurality of functional electrodes include an upper electrode 51A, a first lower electrode 51B, and a second lower electrode 51C. As illustrated in FIG. 26, the present preferred embodiment is also different from the first preferred embodiment in that a plurality of support bodies 58 are provided according to the present preferred embodiment. Other than the above-described points, a piezoelectric bulk wave device 50 according to the present preferred embodiment has the same or similar configuration as that of the piezoelectric bulk wave device 10 according to the first preferred embodiment.

As illustrated in FIG. 25, the upper electrode 51A is provided on the second main surface 14b of the piezoelectric layer 14 and electrically connected to the second lower electrode 51C. A portion of each of the first lower electrode 51B and the second lower electrode 51C is provided on the first main surface 14a of the piezoelectric layer 14. Another portion of each of the first lower electrode 51B and the second lower electrode 51C is provided on the insulating layer 15 of the support 13. The upper electrode 51A and the first lower electrode 51B face each other with the piezoelectric layer 14 interposed therebetween. The first lower electrode 51B and the second lower electrode 51C face each other and are separated from each other with a gap interposed therebetween on the first main surface 14a of the piezoelectric layer 14.

The upper electrode 51A and the first lower electrode 51B are respectively connected to different potentials. A region where the upper electrode 51A and the first lower electrode 51B face each other is an exciting region. The exciting region is positioned inside a peripheral edge of the cavity portion 13a of the support 13 in plan view. When an alternating-current electric field is applied across the upper electrode 51A and the first lower electrode 51B, an acoustic wave is excited in the exciting region.

As described above, the first lower electrode 51B of the first lower electrode 51B and the second lower electrode 51C is a lower electrode that excites the acoustic wave. Meanwhile, the second lower electrode 51C is connected to the upper electrode 51A through a connection electrode 59. Specifically, the connection electrode 59 extends through a side surface of the piezoelectric layer 14 to connect both the above-described electrodes to each other. The side surface of the piezoelectric layer 14 is connected to the first main surface 14a and the second main surface 14b. According to the present preferred embodiment, the connection electrode 59 and the upper electrode 51A are integral with each other. However, the connection electrode 59 and the upper electrode 51A may be provided as separate bodies spaced apart from each other.

The first lower electrode 51B includes a first support portion 51a and a first supported portion 51c. The second lower electrode 51C includes a second support portion 51b and a second supported portion 51d. More specifically, the first supported portion 51c and the second supported portion 51d face each other with the first support portion 51a and the second support portion 51b interposed therebetween. The first support portion 51a is provided on the first main surface 14a of the piezoelectric layer 14. Similarly, the second support portion 51b is also provided on the first main surface 14a of the piezoelectric layer 14. Meanwhile, the first supported portion 51c are provided on the support 13. Similarly, the second support portion 51b is also provided on the support 13. The first lower electrode 51B and the second lower electrode 51C in the functional electrodes support the piezoelectric layer 14 at the first support portion 51a and the second support portion 51b. The first lower electrode 51B and the second lower electrode 51C are supported by the support 13 at the first supported portion 51c and the second supported portion 51d.

Also according to the present preferred embodiment, as in the first preferred embodiment, the cavity portion 13a of the support 13 is superposed on portions of the functional electrodes and the entirety or substantially the entirety of the piezoelectric layer 14 in plan view, and the piezoelectric layer 14 is supported by the functional electrodes. More specifically, a portion of the first lower electrode 51B, a portion of the second lower electrode 51C, and the entirety or substantially the entirety of the upper electrode 51A in the functional electrodes as well as the entirety or substantially the entirety of the piezoelectric layer 14 are superposed on the cavity portion 13a in plan view. The piezoelectric layer 14 is supported by the first lower electrode 51B and the second lower electrode 51C. In this way, the stress from the support 13 is not directly applied to the piezoelectric layer 14, and accordingly, cracks are unlikely to be produced in the piezoelectric layer 14.

The first lower electrode 51B includes a first connection portion 51e. The second lower electrode 51C includes a second connection portion 51f. The first connection portion 51e of the first lower electrode 51B is positioned between the first support portion 51a and the first supported portion 51c. The second connection portion 51f of the second lower electrode 51C is positioned between the second support portion 51b and the second supported portion 51d. In the thickness direction and in the direction perpendicular or substantially perpendicular to the thickness direction, the first connection portion 51e and the second connection portion 51f have a uniform structure and neither of them includes irregularities.

The first support portion 51a, the second support portion 51b, the first supported portion 51c, the second supported portion 51d, the first connection portion 51e, and the second connection portion 51f can be formed as illustrated in, for example, FIGS. 6B and 6C. Specifically, these portions can be formed by removing the entirety or substantially the entirety of the second portion 24B and a portion of the first portion 24A of the piezoelectric substrate 24. In this case, the first connection portion 51e and the second connection portion 51f are formed in a state in which the first lower electrode 51B and the second lower electrode 51C are fixed. Accordingly, in both of the thickness direction and the direction perpendicular or substantially perpendicular to the thickness direction, the first connection portion 51e and the second connection portion 51f have a uniform structure and neither of them includes irregularities.

As illustrated in FIG. 26, the piezoelectric bulk wave device 50 according to the present preferred embodiment includes the plurality of support bodies 58. Specifically, two support bodies 58 are provided in the cavity portion 13a of the support 13. Two support bodies 58 face each other with the first lower electrode 51B interposed therebetween. Furthermore, as illustrated in FIG. 27, two support bodies 58 face each other with the second lower electrode 51C interposed therebetween. Each of the support bodies 58 extends from the cavity portion bottom surface 13b to the piezoelectric layer 14 side. Each of the support bodies 58 supports the piezoelectric layer 14. The support bodies 58 are not necessarily provided.

Also in the piezoelectric bulk wave device 50, the frequency adjustment film 17 illustrated in, for example, FIG. 3 may be provided. In this case, the frequency adjustment film 17 may be indirectly provided on the second main surface 14b of the piezoelectric layer 14 with the upper electrode 51A interposed therebetween.

Also according to the present preferred embodiment, as in the third preferred embodiment, the piezoelectric layer 14 is also supported by the support bodies 58 in addition to the functional electrodes. Thus, the piezoelectric layer 14 is unlikely to be brought into contact with the cavity portion bottom surface 13b. Accordingly, degradation of the electrical characteristics of the piezoelectric bulk wave device 50 can be reduced or prevented.

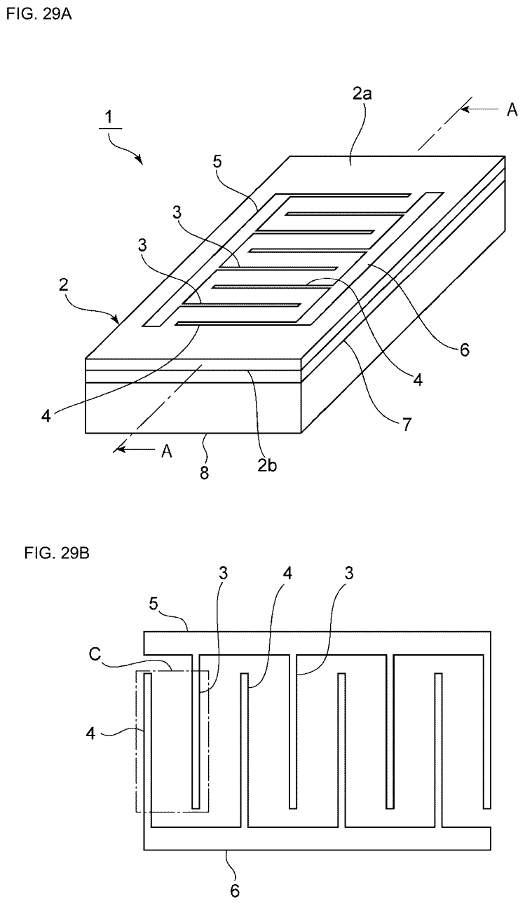

Meanwhile, the cavity portion 13a of the support 13 may be a through hole. For example, in a variant of the eighth preferred embodiment illustrated in FIG. 28, a cavity portion 53a of a support 53 is a through hole provided in the support 53. More specifically, the cavity portion 53a is a through hole continuously provided through a support substrate 56 and an insulating layer 55. Also in this case, cracks are unlikely to be produced in the piezoelectric layer 14 as in the eighth preferred embodiment. Hereinafter, the details of the thickness slip mode are described. Herein, the piezoelectric bulk wave device is one example of acoustic wave devices. Accordingly, the piezoelectric bulk wave device may also be referred to as an acoustic wave device hereinafter. In the following example, “electrodes” correspond to electrode fingers. In the following example, a support corresponds to a support substrate.

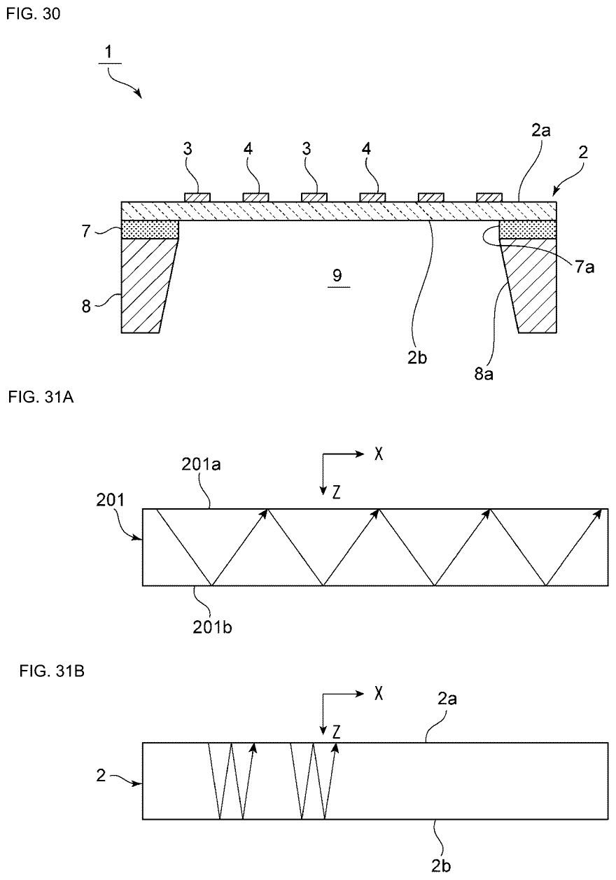

FIG. 29A is a simplified perspective view illustrating the appearance of an acoustic wave device in which a bulk wave in the thickness slip mode is utilized. FIG. 29B is a plan view illustrating an electrode structure on a piezoelectric layer. FIG. 30 is a sectional view taken along line A-A of FIG. 2A.

An acoustic wave device 1 includes a piezoelectric layer 2 composed of LiNbO₃. The piezoelectric layer 2 may be composed of LiTaO₃. Although the cut angle of the LiNbO₃ and LiTaO₃ is a Z cut, the cut angle may be a rotation Y cut or an X cut. The thickness of the piezoelectric layer 2 is not particularly limited. However, in order to effectively excite the thickness slip mode, the thickness of the piezoelectric layer 2 is preferably, for example, greater than or equal to about 40 nm and smaller than or equal to about 1000 nm, and more preferably, greater than or equal to about 50 nm and smaller than or equal to about 1000 nm. The piezoelectric layer 2 includes a first main surface 2a and a second main surface 2b which are opposite from each other. Electrodes 3 and electrodes 4 are provided on the first main surface 2a. Herein, the electrodes 3 are examples of a “first electrode” and the electrodes 4 are examples of a “second electrode”. Referring to FIGS. 29A and 29B, a plurality of electrodes 3 are connected to a first busbar 5. A plurality of electrodes 4 are connected to a second busbar 6. The plurality of electrodes 3 and the plurality of electrodes 4 are interdigitated with each other. The electrodes 3 and the electrodes 4 have a rectangular or substantially rectangular shape and a length direction. The electrodes 3 and the adjacent electrodes 4 face each other in a direction perpendicular or substantially perpendicular to the length direction. Both of the length direction of the electrodes 3 and 4 and the direction perpendicular or substantially perpendicular to the length direction of the electrodes 3 and 4 are directions intersecting the thickness direction of the piezoelectric layer 2. Accordingly, it can also be said that the electrodes 3 and the adjacent electrodes 4 face each other in a direction intersecting the thickness direction of the piezoelectric layer 2. Alternatively, the length direction of the electrodes 3 and 4 may be substituted by the direction perpendicular or substantially perpendicular to the length direction of the electrodes 3 and 4 illustrated in FIGS. 29A and 29B. That is, referring to FIGS. 29A and 29B, the electrodes 3 and 4 may extend in a direction in which the first busbar 5 and the second busbar 6 extend. In this case, the first busbar 5 and the second busbar 6 extend in a direction in which the electrodes 3 and 4 extend in FIGS. 29A and 29B. A plurality structures of pairs of the electrodes 3 and the electrodes 4 are provided in the direction perpendicular or substantially perpendicular to the length direction of the electrodes 3 and 4. In each of the structures of the pairs, a corresponding one of the electrodes 3 connected to one potential and a corresponding one of the electrodes 4 connected to another potential are adjacent to each other. Herein, a case where the electrode 3 and the electrode 4 are adjacent to each other does not refers to a case where the electrode 3 and the electrode 4 are arranged so as to be in direct contact with each other but a case where the electrode 3 and the electrode 4 are arranged with spacing interposed therebetween. Furthermore, when the electrode 3 and the electrode 4 are adjacent to each other, electrodes connected to a hot electrode or a ground electrode including the other electrodes 3 and 4 are not arranged between the electrode 3 and the electrode 4. A number of pairs is not necessarily an integer and may be 1.5 pairs, 2.5 pairs, or the like. The center-to-center distance, that is, the pitch between the electrodes 3 and 4 is preferably, for example, in a range greater than or equal to about 1 μm and smaller than or equal to about 10 μm. Furthermore, the width of the electrodes 3 and 4, that is the dimension of the electrodes 3 and 4 in the facing direction is preferably, for example, in a range greater than or equal to about 50 nm and smaller than or equal to about 1000 nm, and more preferably, in a range greater than or equal to about 150 nm and smaller than or equal to about 1000 nm. The center-to-center distance between the electrodes 3 and 4 is defined as a distance connecting the center, in dimension, of the electrode 3 in the direction perpendicular or substantially perpendicular to the length direction of the electrode 3 (width dimension) and the center, in dimension, of the electrode 4 in the direction perpendicular or substantially perpendicular to the length direction of the electrode 4 (width dimension).

Furthermore, since the Z cut piezoelectric layer is used in the acoustic wave device 1, the direction perpendicular or substantially perpendicular to the length direction of the electrodes 3 and 4 is a direction perpendicular or substantially perpendicular to a polarization direction of the piezoelectric layer 2. This is not necessarily applicable to the case where a piezoelectric body of another cut angle is used as the piezoelectric layer 2. Herein, the term “perpendicular” is not limited only to an exactly perpendicular state but may be used for a substantially perpendicular state (an angle formed between the direction perpendicular to the length direction of the electrodes 3 and 4 and the polarization direction is, for example, in a range of about 90±10′).

A support 8 is laminated on the second main surface 2b side of the piezoelectric layer 2 with an insulating layer 7 interposed therebetween. The insulating layer 7 and the support 8 have a frame shape and, as illustrated in FIG. 30, include through holes 7a and 8a. With these, a cavity portion 9 is provided. The cavity portion 9 is provided so as not to retard vibration of an exciting region C of the piezoelectric layer 2. Accordingly, the support 8 is laminated on the second main surface 2b with the insulating layer 7 interposed therebetween at a position not superposed on portion where the at least one pair of the electrodes 3 and 4 is provided. The insulating layer 7 is not necessarily provided. Accordingly, the support 8 can be laminated directly or indirectly on the second main surface 2b of the piezoelectric layer 2.

The insulating layer 7 is made of, for example, silicone oxide. However, other than silicone oxide, an appropriate insulating material such as, for example, silicon nitride or alumina can be used. The support 8 is made of, for example, Si. The plane orientation of Si in a surface on the piezoelectric layer 2 side may be (100) or (110) or may be (111). The Si of the support 8 is preferably, for example, high-resistance Si with a resistivity of greater than or equal to about 4 kΩcm. However, the support 8 can also be made of an appropriate insulating material or a semiconductor material, for example.

As the material of the support 8, for example, a piezoelectric material such as aluminum oxide, lithium tantalate, lithium niobate, or crystal, any of various types of ceramics such as alumina, magnesia, sapphire, silicon nitride, aluminum nitride, silicon carbide, zirconia, cordierite, mullite, steatite, and forsterite, a dielectric such as diamond or glass, or a semiconductor such as gallium nitride can be used.

The plurality of electrodes 3 and 4 and the first and second busbars 5 and 6 are made of an appropriate metal or alloy such as, for example, Al or AlCu alloy. According to the present preferred embodiment, the electrodes 3 and 4 and the first and second busbars 5 and 6 include, for example, an Al film laminated on a Ti film. An adhesion layer other than the Ti film may be used.

In driving, an alternating-current voltage is applied across the plurality of electrodes 3 and the plurality of electrodes 4. More specifically, the alternating-current voltage is applied across the first busbar 5 and the second busbar 6. Thus, a resonance characteristic utilizing the bulk wave in the thickness slip mode excited in the piezoelectric layer 2 can be obtained. In the acoustic wave device 1, when the thickness of the piezoelectric layer 2 is d and the center-to-center distance between the electrode 3 and the electrode 4 adjacent to each other in any one pair out of the plurality of pairs of the electrodes 3 and 4 is p, d/p is, for example, smaller than or equal to about 0.5. Thus, the bulk wave in the thickness slip mode can be effectively excited, and a good resonance characteristic can be obtained. More preferably, for example, d/p is smaller than or equal to about 0.24. In this case, a more preferable resonance characteristic can be obtained.

Since the acoustic wave device 1 includes the above-described configuration, the quality factor is unlikely to reduce even when the number of pairs of the electrodes 3 and 4 is reduced to reduce the size. The reason for this is that, even when the number of electrode fingers in reflectors on both sides is reduced, propagation losses are small. The reason why the number of the electrode fingers can be reduced is that the bulk wave in the thickness slip mode is utilized. The difference between a Lam wave utilized in the acoustic wave device and the bulk wave in the thickness slip mode is described with reference to FIGS. 31A and 31B.

FIG. 31A is a schematic elevational sectional view for illustrating a Lamb wave propagating in a piezoelectric film of an acoustic wave device as described in Japanese Unexamined Patent Application Publication No. 2012-257019. Here, the wave propagates in a piezoelectric film 201 as indicated by arrows. Here, a first main surface 201a and a second main surface 201b of the piezoelectric film 201 are opposite from each other and the thickness direction connecting the first main surface 201a and the second main surface 201b is the Z direction. The X direction is a direction in which electrode fingers of an IDT electrode are arranged. As illustrated in FIG. 31A, regarding the Lamb wave, the wave propagates in the X direction as illustrated. Although the piezoelectric film 201 vibrates as a whole, since the wave is a plate wave, the wave propagates in the X direction. Accordingly, reflectors are provided on both sides to obtain the resonance characteristic. Thus, propagation losses of the wave are generated, and when the size is reduced, that is, the number of pairs of the electrode fingers is reduced, the quality factor reduces.

In contrast, as illustrated in FIG. 31B, in the acoustic wave device 1, since the vibration displacement occurs in the thickness slip direction, the wave substantially propagates in a direction connecting the first main surface 2a and the second main surface 2b of the piezoelectric layer 2, that is, in the Z direction and resonates. That is, an X direction component of the wave is significantly smaller than a Z direction component of the wave. Since the resonance characteristic can be obtained by the propagation of the wave in the Z direction, even when the number of the electrode fingers of the reflectors is reduced, the propagation losses are unlikely to be generated. Furthermore, even when the number of pairs of electrodes including the electrodes 3 and 4 is reduced so as to further reduce the size, the quality factor is unlikely to reduce.

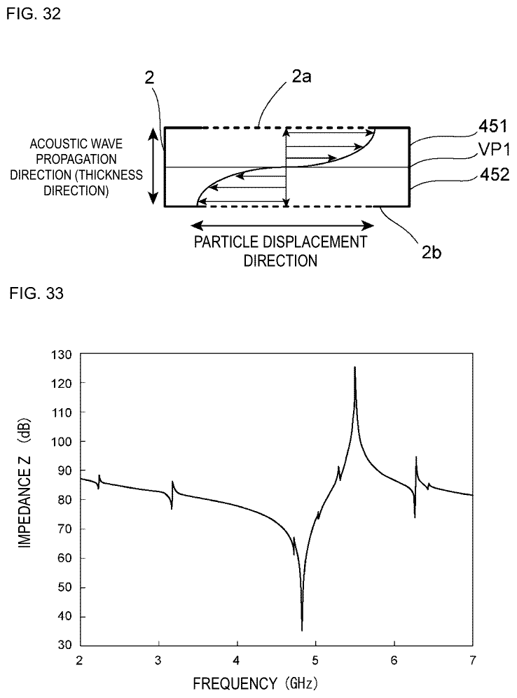

As illustrated in FIG. 32, an amplitude direction of the bulk wave in the thickness slip mode is reversed between a first region 451 included in the exciting region C of the piezoelectric layer 2 and a second region 452 included in the exciting region C. FIG. 32 schematically illustrates the bulk wave when a voltage with which the potential is higher at the electrodes 4 than at the electrodes 3 is applied across the electrodes 3 and the electrodes 4. The first region 451 is, of the exciting region C, a region between the first main surface 2a and a virtual plane VP1 that is perpendicular or substantially perpendicular to the thickness direction of the piezoelectric layer 2 and that bifurcates the piezoelectric layer 2. The second region 452 is, of the exciting region C, a region between the second main surface 2b and the virtual plane VP1.

As described above, at least one pair of the electrodes including the electrode 3 and the electrode 4 are disposed in the acoustic wave device 1. Since the wave does not propagate in the X direction, it is not required that a plurality of pairs of electrodes including the electrodes 3 and 4 are provided. That is, it is sufficient that at least one pair of the electrodes be provided.

For example, the electrode 3 is connected to the hot potential and the electrode 4 is connected to the ground potential. However, the electrode 3 may be connected to the ground potential and the electrode 4 may be connected to the hot potential. According to the present preferred embodiment, as described above, the at least one pair of the electrodes include the electrode connected to the hot potential or the electrode connected to the ground potential, and no floating electrode is provided.

FIG. 33 is a diagram illustrating the resonance characteristic of the acoustic wave device illustrated in FIG. 30. Design parameters of the acoustic wave device 1 with which this resonance characteristic is obtained are as follows.

Piezoelectric layer 2: LiNbO₃ of Euler angles (0°, 0°, 90°) and a thickness of about 400 nm. When seen in the direction perpendicular or substantially perpendicular to the length direction of the electrode 3 and the electrode 4, the length of a region where the electrode 3 and the electrode 4 are superposed on each other, that is, the exciting region C is about 40 μm. The number of pairs of electrodes including the electrodes 3 and 4=21 pairs. The center-to-center distance between electrodes=about 3 μm, the width of the electrodes 3 and 4=about 500 nm, and d/p=about 0.133.

Insulating layer 7: Silicon oxide film having a thickness of about 1 μm.

Support 8: Si.

The length of the exciting region C is a dimension along the length direction of the electrodes 3 and 4 of the exciting region C.

According to the present preferred embodiment, the distance between the electrodes of the electrode pairs including the electrodes 3 and 4 is uniform or substantially uniform throughout the plurality of pairs. That is, the electrodes 3 and the electrodes 4 are arranged at equal or substantially equal pitches.

As clearly seen from FIG. 33, although no reflector is provided, a good resonance characteristic with a fractional bandwidth of, for example, about 12.5% is obtained.

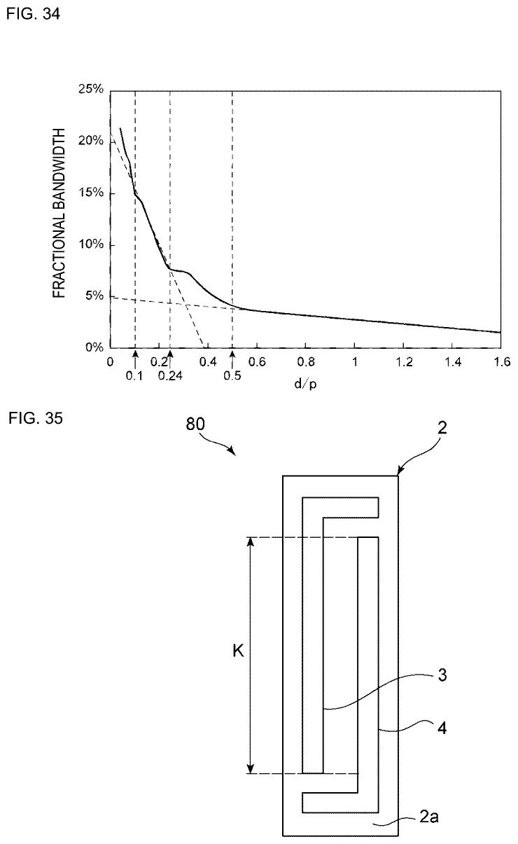

Meanwhile, when the thickness of the piezoelectric layer 2 is d and the center-to-center distance of electrodes between the electrode 3 and the electrode 4 is p, as described above, d/p is, for example, smaller than or equal to about 0.5, and more preferably, smaller than or equal to about 0.24 according to the present preferred embodiment. This is described with reference to FIG. 34.

A plurality of acoustic wave devices are obtained similarly to the acoustic wave device with which the resonance characteristic illustrated in FIG. 33 is obtained except for d/p that is varied. FIG. 34 is a diagram illustrating the relationship between d/p and the fractional bandwidth of the acoustic wave devices as resonators.

As clearly seen from FIG. 34, for example, in the case where d/p>about 0.5, the fractional bandwidth is smaller than about 5% even when d/p is adjusted. In contrast, in the case where d/p≤about 0.5, when d/p is varied within this range, the fractional bandwidth can be greater than or equal to about 5%, that is, a resonator having a high coupling coefficient can be configured. Furthermore, in the case where d/p is smaller than or equal to about 0.24, the fractional bandwidth can be increased to greater than or equal to about 7%. In addition, when d/p is adjusted within this range, a resonator having a broader fractional bandwidth can be obtained, and a resonator having a higher coupling coefficient can be achieved. Thus, it can be understood that, when d/p is, for example, smaller than or equal to about 0.5, a resonator in which the bulk wave in the thickness slip mode is utilized and which has a high coupling coefficient can be configured.

FIG. 35 is a plan view of an acoustic wave device in which the bulk wave in the thickness slip mode is utilized. In an acoustic wave device 80, a pair of the electrode including the electrode 3 and the electrode 4 are provided on the first main surface 2a of the piezoelectric layer 2. In FIG. 35, K is an intersecting width. As described above, in the acoustic wave device according to the present invention, the number of pairs of electrodes may be one. Even in this case, when d/p described above is smaller than or equal to about 0.5, the bulk wave in the thickness slip mode can be effectively excited.

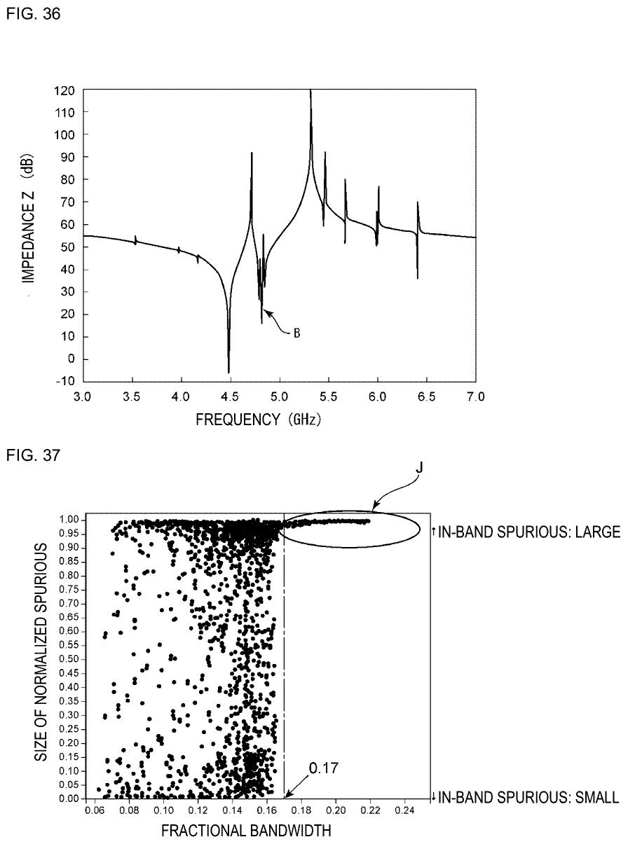

In the acoustic wave device 1, preferably, with respect to the exciting region C being a region in which any of adjacent electrodes 3 and 4 in the plurality of electrodes 3 and 4 are superposed on each other when seen in a direction in which these adjacent electrodes 3 and 4 face each other, a metallization ratio MR of these adjacent electrodes 3 and 4 desirably satisfies MR 1.75(d/p)+0.075. In this case, a spurious emission can be effectively reduced. This is described with reference to FIGS. 36 and 37. FIG. 36 is a reference diagram illustrating an example of the resonance characteristic of the acoustic wave device 1. A Spurious emission indicated by arrow B appears between a resonant frequency and an anti-resonant frequency. Here, d/p is about 0.08 and the Euler angles of LiNbO₃ is (0°, 0°, 90°). Furthermore, the metallization ratio MR is about 0.35.

The metallization ratio MR is described with reference to FIG. 29B. In the electrode structure illustrated in FIG. 29B, when a pair of the electrodes 3 and 4 are focused on, it is assumed that only this pair of the electrodes 3 and 4 are provided. In this case, a portion surrounded by dotted-chain lines is the exciting region C. When the electrode 3 and the electrode 4 are seen in the direction perpendicular or substantially perpendicular to the length direction of the electrodes 3 and 4, that is, the facing direction, this exciting region C is a region in the electrode 3 superposed on the electrode 4, a region in the electrode 4 superposed on the electrode 3, and a region in a region between the electrode 3 and the electrode 4 where the electrode 3 and the electrode 4 are superposed on each other. The area of the electrodes 3 and 4 in the exciting region C to the area of the exciting region C is the metallization ratio MR. That is, the metallization ratio MR is the ratio of the area of metallization portions to the area of the exciting region C.

When a plurality of pairs of the electrodes are provided, it is sufficient that the ratio of metallization portions included in all of the exciting regions to the sum of the areas of the exciting regions be regarded as MR.

FIG. 37 is a diagram illustrating the relationship between the fractional bandwidth in the case where many acoustic wave resonators are configured according to the present preferred embodiment and a phase rotation amount of the impedance of a spurious emission normalized with about 180 degrees as the size of the spurious emission. The fractional bandwidth is adjusted by changing the film thickness of the piezoelectric layer and the dimensions of the electrodes in various manners. Although FIG. 37 is a result of the case where the piezoelectric layer formed of Z-cut LiNbO₃ is used, the tendency is also the same as or similar to a case where the piezoelectric layer of another cut angle is used.

The spurious emission is large and reaches to about 1.0 in a region surrounded by an ellipse J in FIG. 37. As clearly seen from FIG. 37, when the fractional bandwidth exceeds about 0.17, that is, exceed about 17%, a large spurious emission of a spurious level of greater than or equal to about 1 appears in the pass band even when parameters configuring the fractional bandwidth are varied. That is, as in the resonance characteristic illustrated in FIG. 36, a large spurious emission indicated by the arrow B appears in the band width. Accordingly, the fractional bandwidth is preferably, for example, smaller than or equal to about 17%. In this case, the spurious emission can be reduced by adjusting the film thickness of the piezoelectric layer 2, the dimensions of the electrodes 3 and 4, or the like.

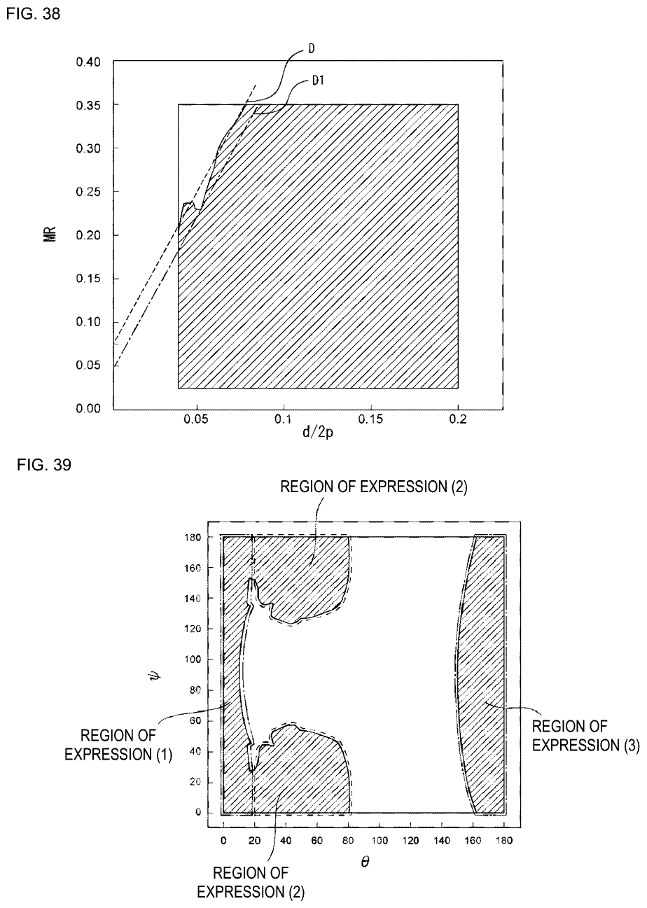

FIG. 38 is a diagram illustrating the relationships of d/2p, the metallization ratio MR, and the fractional bandwidth. In the acoustic wave device, various acoustic wave devices with different d/2p values and MRs are configured, and the fractional bandwidth is measured. A hatched portion on the right side of a broken line D of FIG. 38 is a region where the fractional bandwidth is smaller than or equal to about 17%. A boundary between this hatched region and a non-hatched region is represented by MR=about 3.5(d/2p)+0.075. That is, MR=about 1.75(d/p)+0.075. Accordingly, preferably, for example, MR≤about 1.75(d/p)+0.075. In this case, the fractional bandwidth of smaller than or equal to about 17% is easily obtained. A region on the right side of MR=about 3.5(d/2p)+0.05 indicated by a dotted-chain line D1 in FIG. 38 is more preferable. That is, when MR≤about 1.75(d/p)+0.05, the fractional bandwidth of smaller than or equal to about 17% can be reliably obtained.

FIG. 39 is a diagram illustrating a map of the fractional bandwidth with respect to the Euler angles (0°, θ, ψ) of LiNbO₃ when d/p is caused to limitlessly approach 0. Hatched portions in FIG. 39 are regions where a fractional bandwidth of at least greater than or equal to about 5% can be obtained, and, when ranges of those regions are approximated, the ranges are given by the following Expression (1), Expression (2), and Expression (3).

(0±10°,0 to 20°,any ψ) Expression (1)

(0±10°,20 to 80°,0 to 60°(1−(θ−50)²/900)^{1/2}) or (0±10°,20 to 80°,[180°−60°(1−(θ−50)²/900)^{1/2}] to 180°) Expression (2)

(0±10°,[180°−30° (1−(ψ−90)²/8100)^{1/2}] to 180°, any ψ) Expression (3)

Accordingly, in the case of the Euler angles ranges of Expression (1), Expression (2), or Expression (3), it is preferable that the fractional bandwidth can be sufficiently increased. This is similarly applicable to the case where the piezoelectric layer 2 is a lithium tantalate layer.

In the piezoelectric bulk wave device according to the first to seventh preferred embodiments or the variant in which the bulk wave in the thickness slip mode is utilized, as described above, d/p is preferably, for example, smaller than or equal to about 0.5, and more preferably smaller than or equal to about 0.24. In this way, a more preferable resonance characteristic can be obtained. Furthermore, in the piezoelectric bulk wave device according to the first to seventh preferred embodiments or the variant in which the bulk wave in the thickness slip mode is utilized, as described above, preferably, for example, MR about 1.75(d/p)+0.075 is satisfied. In this case, the spurious emission can be more reliably reduced or prevented.

The functional electrodes in the piezoelectric bulk wave device according to the first to seventh preferred embodiments or the variant in which the bulk wave in the thickness slip mode is utilized may be the functional electrodes including a pair of the electrodes illustrated in FIG. 35.

The piezoelectric layer in the piezoelectric bulk wave device according to the first to seventh preferred embodiments or the variant in which the bulk wave in the thickness slip mode is utilized is preferably, for example, a lithium niobate layer or a lithium tantalate layer. The Euler angles (Φ, θ, ψ) of lithium niobate or lithium tantalate of which the piezoelectric layer is composed are preferably in the ranges of Expression (1), Expression (2), or Expression (3) described above. In this case, the fractional bandwidth can be sufficiently increased.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric bulk wave device comprising:
a support that includes a support substrate;
a piezoelectric layer including a first main surface on a support side and a second main surface opposite from the first main surface; and
at least one functional electrode at least a portion of which is on at least one of the first main surface and the second main surface of the piezoelectric layer; wherein
the at least one functional electrode is supported by the support and includes a functional electrode including a portion on the first main surface of the piezoelectric layer;
a cavity portion is provided in the support, the cavity portion is superposed on a portion of the functional electrode and an entirety or substantially an entirety of the piezoelectric layer in plan view; and
the piezoelectric layer is supported by the functional electrode supported by the support.

2. The piezoelectric bulk wave device according to claim 1, wherein
the support includes an insulating layer on the support substrate; and
a portion of the functional electrode is on the insulating layer.

3. The piezoelectric bulk wave device according to claim 1, wherein the functional electrode supported by the support is an interdigital transducer electrode that includes a pair of busbars and a plurality of electrode fingers.

4. The piezoelectric bulk wave device according to claim 3, wherein the pair of busbars include a supported portion on the support and a support portion on the first main surface of the piezoelectric layer to support the piezoelectric layer.

5. The piezoelectric bulk wave device according to claim 3, wherein the piezoelectric layer is a lithium tantalate layer or a lithium niobate layer.

6. The piezoelectric bulk wave device according to claim 5, wherein the piezoelectric bulk wave device structured to generate a bulk wave in a thickness slip mode.

7. The piezoelectric bulk wave device according to claim 5, wherein, when a thickness of the piezoelectric layer is d and a center-to-center distance between electrode fingers of the plurality of electrode fingers adjacent to each other is p, d/p is smaller than or equal to about 0.5.

8. The piezoelectric bulk wave device according to claim 7, wherein d/p is smaller than or equal to about 0.24.

9. The piezoelectric bulk wave device according to claim 7, wherein, when seen in a direction in which the electrode fingers adjacent to each other face each other, a region where the electrode fingers adjacent each other are superposed on each other is an exciting region, and, in a case where a metallization ratio of the plurality of electrode fingers to the exciting region is MR, MR≤about 1.75(d/p)+0.075 is satisfied.

10. The piezoelectric bulk wave device according to claim 6, wherein Euler angles (Φ, θ, ψ) of the lithium niobate layer or the lithium tantalate layer as the piezoelectric layer are in ranges of Expression (1), Expression (2), or Expression (3):
(0±10°,0 to 20°,any ψ) Expression (1);
(0±10°,20 to 80°,0 to 60° (1−(θ−50)²/900)^{1/2})or(0±10°,20 to 80°,[180°−60° (1−(θ−50)²/900)^{1/2}] to 180°) Expression (2); and
(0±10°,[180°−30° (1−(ψ−90)²/8100)^{1/2}] to 180°,any ψ) Expression (3).

11. The piezoelectric bulk wave device according to claim 1, wherein
the functional electrode includes a lower electrode including a portion on the first main surface of the piezoelectric layer and another portion on the support, and an upper electrode on the second main surface; and
the upper electrode and the lower electrode are opposite to each other with the piezoelectric layer interposed therebetween.

12. The piezoelectric bulk wave device according to claim 1, wherein the piezoelectric layer is supported only by the functional electrode.

13. The piezoelectric bulk wave device according to claim 1, wherein
the functional electrode supported by the support is an interdigital transducer electrode including a pair of busbars and a plurality of electrode fingers;
the cavity portion is a recessed portion in the support;
the support includes a cavity portion bottom surface defined by a bottom surface of the recessed portion;
the piezoelectric bulk wave device further includes at least one support body extending from the cavity portion bottom surface to a piezoelectric layer side and supporting the piezoelectric layer; and
the support body is in contact with the functional electrode.

14. The piezoelectric bulk wave device according to claim 1, wherein
the cavity portion is a recessed portion in the support;
the support includes a cavity portion bottom surface defined by a bottom surface of the recessed portion;
the piezoelectric bulk wave device further includes at least one support body extending from the cavity portion bottom surface to a piezoelectric layer side and supporting the piezoelectric layer; and
the support body is not in contact with the functional electrode.

15. The piezoelectric bulk wave device according to claim 13, wherein the support includes an insulating layer on the support substrate, and the support body is made of a same material as a material of the insulating layer and is integral with the insulating layer.

16. The piezoelectric bulk wave device according to claim 13, wherein
the support body is a separate body from the support, and
the support body is made of metal.

17. The piezoelectric bulk wave device according to claim 13, wherein
the support includes a cavity portion side wall surface defining a side wall surface of the recessed portion and connected to the cavity portion bottom surface; and
the support body is in contact with the cavity portion side wall surface.

18. The piezoelectric bulk wave device according to claim 13, wherein the at least one support body includes a plurality of support bodies.

19. The piezoelectric bulk wave device according to claim 1, wherein
the functional electrode supported by the support includes a supported portion on the support, a support portion on the first main surface of the piezoelectric layer and supporting the piezoelectric layer, and a connection portion positioned between the support portion and the supported portion; and
the connection portion does not include an irregularity in either of a thickness direction or a direction perpendicular or substantially perpendicular to the thickness direction.

20. The piezoelectric bulk wave device according to claim 1, further comprising a frequency adjustment film on the second main surface of the piezoelectric layer and superposed on the functional electrode in plan view.

21. A method for manufacturing a piezoelectric bulk wave device, the method comprising:
providing an interdigital transducer electrode including a pair of busbars and a plurality of electrode fingers on a third main surface of a piezoelectric substrate including the third main surface and a fourth main surface opposite from each other;
forming a multilayer body including the piezoelectric substrate and a support including a support substrate;
forming a piezoelectric layer including a first main surface corresponding to the third main surface and a second main surface opposite from the first main surface by grinding a fourth main surface side of the piezoelectric substrate so as to reduce a thickness of the piezoelectric substrate; and
forming a cavity portion in the support; wherein
in plan view, the piezoelectric substrate includes a first portion superposed on a portion of the support in which the cavity portion is provided and a second portion not superposed on the portion of the support in which the cavity portion is provided; and
in the forming of the piezoelectric layer, at least an entirety or substantially an entirety of the second portion of the piezoelectric substrate is removed.

22. The method according to claim 21, further comprising:
providing a sacrificial layer on the third main surface of the piezoelectric substrate to cover a portion of the pair of busbars of the interdigital transducer electrode and the plurality of electrode fingers;
providing a first insulating layer on the third main surface of the piezoelectric substrate to cover the sacrificial layer and the electrode fingers;
providing a second insulating layer on one main surface of the support substrate; and
providing a through hole in the piezoelectric layer extending to the sacrificial layer after the forming of the piezoelectric layer; wherein
in the forming of the multilayer body, the first insulating layer and the second insulating layer are joined to each other to form an insulating layer; and
in the forming of the cavity portion, the cavity portion is formed in the support by removing the sacrificial layer by utilizing the through hole.

23. The method according to claim 22, wherein
in the providing of the sacrificial layer, at least one support body forming portion defined by a hole extending through the sacrificial layer is formed;
in the providing of the first insulating layer, the first insulating layer is provided to enable the support body forming portion of the sacrificial layer to be filled; and
in the forming of the cavity portion, the cavity portion and the at least one support body are formed in the support by removing the sacrificial layer by utilizing the through hole.
